(19) United States
(12) Patent Application Publication
(10) Pub. No.: US 2024/0079432 A1
(43) Pub. Date: Mar. 7, 2024

(54) PHOTODETECTOR AND ELECTRONIC APPARATUS

(71) Applicant: Sony Semiconductor Solutions Corporation, Kanagawa (JP)

(72) Inventor: Yuichiro Suzuki, Osaka (JP)

(21) Appl. No.: 18/261,736

(22) PCT Filed: Jan. 12, 2022
(86) PCT No.: PCT/JP2022/000692

§ 371 Date: Jul. 17, 2023

(30) Foreign Application Priority Data
Mar. 4, 2021 (JP) 2021-034739

(51) Int. Cl. H01L 27/146

(52) U.S. Cl. CPC H01L 27/1463; H01L 27/14603; H01L 27/14627; H01L 27/14645; G01S 7/4816

(57) ABSTRACT

The present disclosure suppresses deterioration of white spot and dark current characteristics. A photodetector includes a semiconductor layer having a first surface and a second surface located opposite to each other and provided with an element isolation region on a side of the first surface, a photoelectric converter provided in the semiconductor layer, and a transistor provided adjacent to the photoelectric converter on the side of the first surface of the semiconductor layer across the element isolation region. Then, the element isolation region includes a conductive film provided in a groove on the side of the first surface of the semiconductor layer with the first insulating film interposed therebetween, and a second insulating film provided on the side of the first surface of the semiconductor layer so as to overlap the conductive film.

### TECHNICAL FIELD

The present technology (technology of the present disclosure) relates to a photodetector and an electronic apparatus, and particularly relates to a technology effective when applied to a photodetector having a field effect transistor adjacent to a photoelectric converter across an element isolation region and an electronic apparatus including the photodetector.

### BACKGROUND ART

As a photodetector, a solid-state imaging device is known. The solid-state imaging device includes a read circuit that reads a signal charge photoelectrically converted by a photoelectric converter. The read circuit includes pixel transistors such as an amplification transistor, a selection transistor, and a reset transistor. The pixel transistors and the photoelectric converter are mounted on the same semiconductor layer.

Patent Document 1 discloses a solid-state imaging device including a photoelectric converter that photoelectrically converts light incident from a second surface (light incident surface) of a first surface and a second surface located on opposite sides of a semiconductor layer, and a pixel transistor provided on the side of the second surface of the semiconductor layer. Then, the pixel transistor is configured in an element formation region (active region) defined by an element isolation region having a shallow trench isolation (STI) structure on the side of the first surface of the semiconductor layer.

### CITATION LIST

### Patent Document

Patent Document 1: Japanese Patent Application Laid-Open No. 2018-148116

### SUMMARY OF THE INVENTION

### Problems to be Solved by the Invention

Meanwhile, the pixel transistor includes a field effect transistor. In a case where the pixel transistor is disposed adjacent to the photoelectric converter across the element isolation region on the side of the first surface of the semiconductor layer, dielectric polarization of the element isolation region occurs due to a fringe electric field when the pixel transistor is driven. As a result, electrons are induced at an interface between the side of the photoelectric converter of the element isolation region and the semiconductor layer, and pinning at an end of the element isolation region is released, which causes deterioration of white spot and dark current characteristics.

Since there is a possibility that the deterioration of the white spot and dark current characteristics becomes more remarkable as a width of the element isolation region is decreased due to miniaturization of pixels, there is room for improvement.

An object of the present technology is to suppress deterioration of white spot and dark current characteristics.

### Solutions to Problems

(1) A photodetector according to an aspect of the present technology includes
a semiconductor layer having a first surface and a second surface located opposite to each other and provided with an element isolation region on a side of the first surface,
a photoelectric converter provided in the semiconductor layer, and
a transistor provided adjacent to the photoelectric converter on the side of the first surface of the semiconductor layer across the element isolation region.

Then, the element isolation region includes a conductive film provided in a groove on the side of the first surface of the semiconductor layer with the first insulating film interposed therebetween, and a second insulating film provided on the side of the first surface of the semiconductor layer so as to overlap the conductive film.

(2) An electronic apparatus according to another aspect of the present technology includes a photodetector, an optical lens that forms an image of image light from a subject on an imaging surface of the photodetector, and a signal processing circuit that performs signal processing on a signal output from the photodetector.

Then, the photodetector includes a semiconductor layer having a first surface and a second surface located opposite to each other and provided with an element isolation region on a side of the first surface, a photoelectric converter provided in the semiconductor layer, and a transistor provided adjacent to the photoelectric converter on the side of the first surface of the semiconductor layer across the element isolation region.

Then, the element isolation region includes a conductive film provided in a groove on the side of the first surface of the semiconductor layer with the first insulating film interposed therebetween, and a second insulating film provided on the side of the first surface of the semiconductor layer so as to overlap the conductive film.

### BRIEF DESCRIPTION OF DRAWINGS

FIG. 1 is a plan layout diagram schematically illustrating a configuration example of a solid-state imaging device according to a first embodiment of the present technology.

FIG. 2 is a block diagram illustrating a configuration example of the solid-state imaging device according to the first embodiment of the present technology.

FIG. 3 is an equivalent circuit diagram illustrating a configuration example of a pixel block and a read circuit mounted on the solid-state imaging device according to the first embodiment of the present technology.

FIG. 4A is a plan layout diagram of the pixel block and a pixel transistor mounted on the solid-state imaging device according to the first embodiment of the present technology.

FIG. 4B is a plan view illustrating a planar pattern of a conductive film included in an element isolation region in FIG. 4A.

FIG. 5 is an enlarged plan view of a main part of a first pixel group of the pixel block in FIG. 4A.

FIG. 6 is an enlarged plan view of a main part of a second pixel group of the pixel block in FIG. 4A.

FIG. 7 is a sectional view schematically illustrating a sectional structure taken along a line a5-a5 in FIG. 5.

FIG. 8 is a sectional view schematically illustrating a sectional structure taken along a line a6-a6 in FIG. 6.

FIG. 9 is a sectional view schematically illustrating a sectional structure taken along a line b6-b6 in FIG. 6.

FIG. 10 is an enlarged sectional view of a main part in which a part of FIG. 9 is enlarged.

FIG. 11 is a diagram illustrating a band structure in a case where p-type polycrystalline silicon is used as a conductive material included in the conductive film of the element isolation region.

FIG. 12 is a sectional view of a main part illustrating a comparative example.

FIG. 13 is a diagram illustrating a first modification of the solid-state imaging device according to the first embodiment of the present technology, and is a diagram illustrating a band structure in a case where a metal having a deeper work function than a p-type semiconductor region is used as the conductive material included in the conductive film of the element isolation region.

FIG. 14 is a diagram illustrating a second modification of the solid-state imaging device according to the first embodiment of the present technology, and is a diagram illustrating a band structure when a negative bias is applied to the conductive film in the element isolation region.

FIG. 15 is a schematic sectional view of a main part illustrating a third modification of the solid-state imaging device according to the first embodiment of the present technology.

FIG. 16 is a diagram illustrating a plan layout of a pixel block and a pixel transistor mounted on a solid-state imaging device according to a second embodiment of the present technology.

FIG. 17 is a diagram illustrating a plan layout of a pixel block and a pixel transistor mounted on a solid-state imaging device according to a third embodiment of the present technology.

FIG. 18 is a diagram illustrating a plan layout of a pixel block and a pixel transistor mounted on a solid-state imaging device according to a fourth embodiment of the present technology.

FIG. 19A is an equivalent circuit diagram illustrating a configuration example of a pixel block and a read circuit mounted on a solid-state imaging device according to a fifth embodiment of the present technology.

FIG. 19B is a diagram illustrating a plan layout of a pixel block and a pixel transistor mounted on the solid-state imaging device according to the fifth embodiment of the present technology.

FIG. 20A is an equivalent circuit diagram illustrating a configuration example of a pixel block and a read circuit mounted on a solid-state imaging device according to a sixth embodiment of the present technology.

FIG. 20B is a diagram illustrating a plan layout of a pixel block and a pixel transistor mounted on the solid-state imaging device according to the sixth embodiment of the present technology.

FIG. 21A is an equivalent circuit diagram illustrating a configuration example of a pixel block and a read circuit mounted on a solid-state imaging device according to a seventh embodiment of the present technology.

FIG. 21B is a diagram illustrating a plan layout of a pixel block and a pixel transistor mounted on the solid-state imaging device according to the seventh embodiment of the present technology.

FIG. 22A is an equivalent circuit diagram illustrating a configuration example of a pixel block and a read circuit mounted on a solid-state imaging device according to an eighth embodiment of the present technology.

FIG. 22B is a diagram illustrating a plan layout of a pixel block and a pixel transistor mounted on the solid-state imaging device according to the eighth embodiment of the present technology.

FIG. 23 is a sectional view of a main part schematically illustrating an example of a solid-state imaging device according to a ninth embodiment of the present technology.

FIG. 24 is a plan view of a main part schematically illustrating an example of a solid-state imaging device according to a tenth embodiment of the present technology.

FIG. 25 is a schematic sectional view illustrating a sectional structure taken along a line a24-a24 in FIG. 24.

FIG. 26 is a schematic sectional view illustrating a sectional structure taken along a line b24-b24 in FIG. 24.

FIG. 27 is a schematic sectional view illustrating a modification of the solid-state imaging device according to the tenth embodiment of the present technology.

FIG. 28 is a diagram illustrating a schematic configuration of an electronic apparatus according to an eleventh embodiment of the present technology.

### MODE FOR CARRYING OUT THE INVENTION

Hereinafter, embodiments of the present technology will be described in detail with reference to the drawings.

In the illustration of the drawings referred to in the following description, the same or similar parts are denoted by the same or similar reference signs. It should be noted that the drawings are schematic, and a relationship between a thickness and a planar dimension, a ratio of the thicknesses between layers, and the like are different from actual ones. Therefore, specific thicknesses and dimensions should be determined in consideration of the following description.

In addition, it goes without saying that dimensional relationships and ratios are partly different among the drawings. Furthermore, the effects described herein are merely examples and are not limited, and other effects may be provided.

In addition, the following embodiments illustrate a device and a method for embodying the technical idea of the present technology, and do not specify the configuration as follows. That is, various modifications can be made to the technical idea of the present technology within the technical scope described in the claims.

Furthermore, the definitions of directions such as up and down in the following description are merely defined for convenience of description, and do not limit the technical idea of the present technology. For example, it is a matter of course that when an object is observed by rotating the object by 90°, the up and down are converted into and read as left and right, and when the object is observed by rotating the object by 180°, the up and down are inverted and read.

In addition, in the following embodiments, a case will be exemplarily described where a first conductivity type is n-type and a second conductivity type is p-type. However, the conductivity types may be selected in an opposite relationship, and the first conductivity type may be p-type and the second conductivity type may be n-type.

Furthermore, in the following embodiments, in three directions orthogonal to each other in a space, a first direction and a second direction orthogonal to each other in the same plane are defined as an X direction and a Y direction, respectively, and a third direction orthogonal to the first direction and the second direction is defined as a Z direction. Then, in the following embodiments, a thickness direction of a semiconductor layer 21 (described later) will be described as the Z direction.

### First Embodiment

In a first embodiment, an example in which the present technology is applied to a solid-state imaging device that is a back-illuminated complementary metal oxide semiconductor (CMOS) image sensor will be described as a photodetector.

<<Overall Configuration of Solid-State Imaging Device>>

First, an overall configuration of a solid-state imaging device 1 will be described.

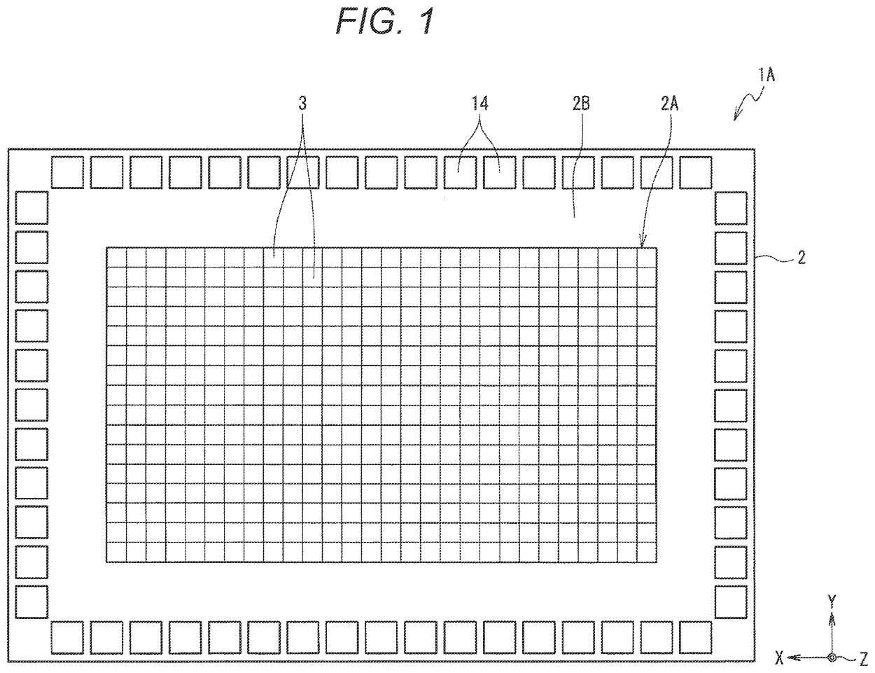

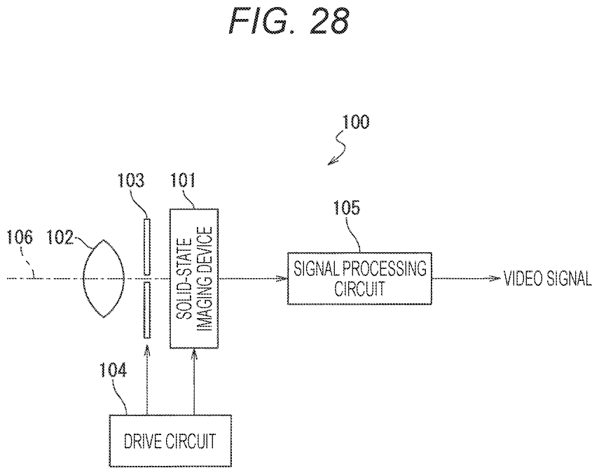

As illustrated in FIG. 1, a solid-state imaging device 1A according to the first embodiment of the present technology mainly includes a semiconductor chip 2 having a rectangular two-dimensional planar shape in plan view. That is, the solid-state imaging device 1A is mounted on the semiconductor chip 2. As illustrated in FIG. 28, the solid-state imaging device 1A (101) receives image light (incident light 106) from a subject through an optical lens 102, converts an amount of the incident light 106 formed as an image on an imaging surface into an electrical signal for each pixel, and outputs the electrical signal as a pixel signal.

As illustrated in FIG. 1, the semiconductor chip 2 on which the solid-state imaging device 1A is mounted includes, in a two-dimensional plane including the X direction and the Y direction orthogonal to each other, a rectangular pixel region 2A provided in a central portion, and a peripheral region 2B provided outside the pixel region 2A so as to surround the pixel region 2A.

The pixel region 2A is, for example, a light receiving surface that receives light condensed by the optical lens (optical system) 102 illustrated in FIG. 28. Then, in the pixel region 2A, a plurality of pixels 3 is arranged in a matrix in the two-dimensional plane including the X direction and the Y direction. In other words, the pixels 3 are repeatedly arranged in the X direction and the Y direction orthogonal to each other in the two-dimensional plane.

As illustrated in FIG. 1, a plurality of bonding pads 14 is disposed in the peripheral region 2B. Each of the plurality of bonding pads 14 is aligned, for example, along four sides in the two-dimensional plane of the semiconductor chip 2. Each of the plurality of bonding pads 14 is an input-output terminal used when the semiconductor chip 2 is electrically connected to an external device.

<Logic Circuit>

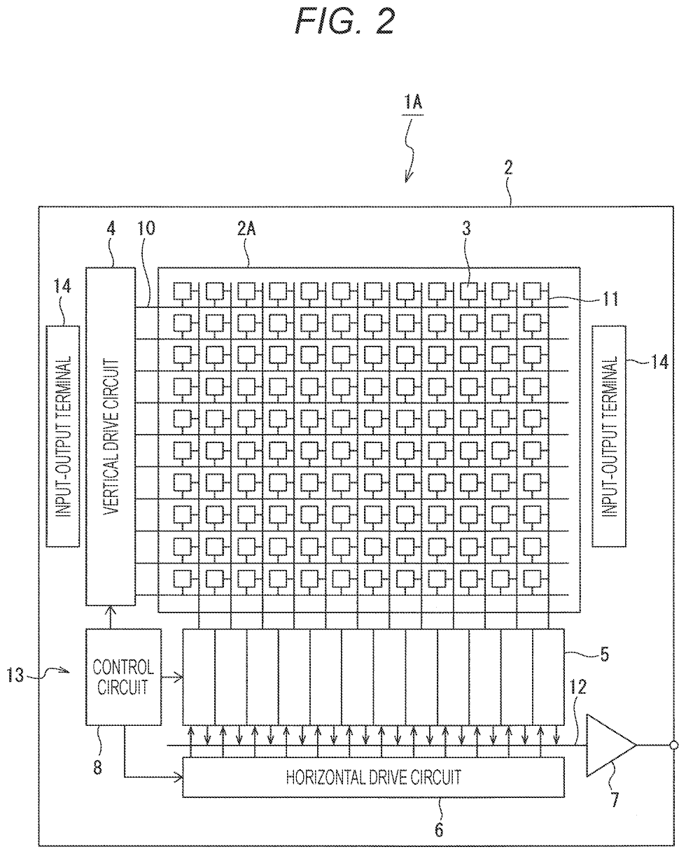

As illustrated in FIG. 2, the semiconductor chip 2 includes a logic circuit 13 including a vertical drive circuit 4, a column signal processing circuit 5, a horizontal drive circuit 6, an output circuit 7, a control circuit 8, and the like. The logic circuit 13 includes, for example, a complementary MOS (CMOS) circuit including an n-channel conductive metal oxide semiconductor field effect transistor (MOSFET) and a p-channel conductive MOSFET as field effect transistors.

The vertical drive circuit 4 includes, for example, a shift register. The vertical drive circuit 4 sequentially selects a desired pixel drive line 10, supplies a pulse for driving the pixels 3 to the selected pixel drive line 10, and drives each pixel 3 row by row. That is, the vertical drive circuit 4 selectively scans each pixel 3 in the pixel region 2A sequentially in a vertical direction row by row, and supplies a pixel signal from the pixel 3 based on a signal charge generated in accordance with the amount of received light by a photoelectric conversion element of each pixel 3 to the column signal processing circuit 5 through a vertical signal line 11.

The column signal processing circuit 5 is arranged, for example, for every column of the pixels 3 and performs signal processing, such as noise removal on signals output from the pixels 3 of one row, for every pixel column. For example, the column signal processing circuit 5 performs signal processing such as correlated double sampling (CDS) for removing pixel-specific fixed pattern noise and analog digital (AD) conversion.

The horizontal drive circuit 6 includes, for example, a shift register. The horizontal drive circuit 6 sequentially outputs horizontal scanning pulses to the column signal processing circuits 5 to sequentially select each of the column signal processing circuits 5, and causes each of the column signal processing circuits 5 to output the pixel signal subjected to the signal processing to a horizontal signal line 12.

The output circuit 7 performs signal processing on pixel signals sequentially supplied from each of the column signal processing circuits 5 through the horizontal signal line 12, and outputs the signals. As the signal processing, for example, buffering, black level adjustment, column variation correction, various digital signal processing, and the like can be used.

The control circuit 8 generates, on the basis of a vertical synchronization signal, a horizontal synchronization signal, and a master clock signal, a clock signal or a control signal in accordance with which the vertical drive circuit 4, the column signal processing circuit 5, the horizontal drive circuit 6, and the like operate. Then, the control circuit 8 outputs the clock signal or control signal thus generated to the vertical drive circuit 4, the column signal processing circuit 5, the horizontal drive circuit 6, and the like.

<Pixel Block>

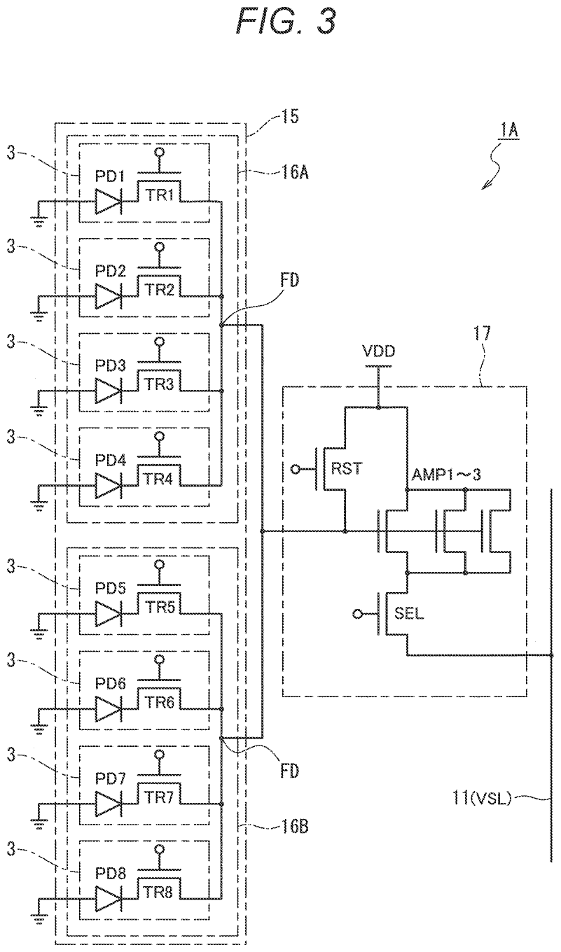

The semiconductor chip 2 includes a pixel block 15 and a read circuit 17 illustrated in FIG. 3. The pixel block 15 includes, but not limited to, two pixel groups (a first pixel group 16A and a second pixel group 16B) as illustrated in FIG. 3. Then, each of the first pixel group 16A and the second pixel group 16B includes four pixels 3 and one charge holding region (floating diffusion) FD shared by the four pixels 3. That is, the pixel block 15 includes eight pixels 3 and two charge holding regions FD. Then, one read circuit 17 is connected to each of the two charge holding regions FD of the pixel block 15. That is, in the pixel block 15, the eight pixels 3 share one read circuit 17, and the output of each of the eight pixels 3 is input to the shared read circuit 17.

Each pixel 3 of the pixel block 15 has a common component. In FIG. 3, in order to distinguish the components of each pixel 3 from each other, identification numbers (1, 2, 3, 4, 5, 6, 7, and 8) are added to the end of the reference signs (for example, PD and TR described later) of the components of each pixel 3. In the following, in a case where it is necessary to distinguish the components of each pixel 3 from each other, the identification number is attached to the end of the reference sign of the component of each pixel 3, but in a case where it is not necessary to distinguish the components of each pixel 3 from each other, the identification number at the end of the reference sign of the component of each pixel 3 is omitted.

As illustrated in FIG. 3, each of the eight pixels 3 included in one pixel block 15 includes a photoelectric conversion element PD (PD1, PD2, PD3, PD4, PD5, PD6, PD7, and PD8) and a transfer transistor TR (TR1, TR2, TR3, TR4, TR5, TR6, TR7, and TR8) that transfers signal charges photoelectrically converted by the photoelectric conversion element PD to the charge holding region FD.

The photoelectric conversion element PD generates a signal charge corresponding to the amount of received light. The photoelectric conversion element PD has a cathode side electrically connected to a source region of the transfer transistor TR, and an anode side electrically connected to a reference potential line (for example, ground). As the photoelectric conversion element PD, for example, a photodiode is used. A drain region of the transfer transistor TR is electrically connected to the charge holding region FD.

The transfer transistor TR has a gate electrode electrically connected to a transfer transistor drive line among the pixel drive lines 10 (see FIG. 2). The charge holding region FD temporarily holds (accumulates) the signal charge transferred from the photoelectric conversion element PD via the transfer transistor TR.

As illustrated in FIG. 3, the read circuit 17 reads the signal charge held in the charge holding region FD, and outputs a pixel signal based on this signal charge. The read circuit 17 includes, but not limited to, for example, three amplification transistors AMP1, AMP2, and AMP3, a selection transistor SEL, and a reset transistor RST as pixel transistors. These pixel transistors (AMP1 to AMP3, SEL, and RST) include, as a field effect transistor, a MOSFET having, for example, a gate insulating film formed by a silicon oxide (SiO₂) film, a gate electrode, and a pair of main electrode regions functioning as a source region and a drain region. Furthermore, these pixel transistors may be a metal insulator semiconductor FET (MISFET) whose gate insulating film is a silicon nitride (Si₃N₄) film or a laminated film of a silicon nitride film and a silicon oxide film.

The source region of each of the three amplification transistors AMP1 to AMP3 is electrically connected to the drain region of the selection transistor SEL. The drain region of each of the three amplification transistors AMP1 to AMP3 is electrically connected to a power supply line VDD and the drain region of the reset transistor RST. Then, the gate electrode of each of the three amplification transistors AMP1 to AMP3 is electrically connected to the charge holding region FD of each of the first pixel group 16A and the second pixel group 16B and the source region of the reset transistor RST.

The source region of the selection transistor SEL is electrically connected to the vertical signal line 11. The drain region of the selection transistor SEL is electrically connected to the source region of each of the three amplification transistors AMP1 to AMP3. Then, the gate electrode of the selection transistor SEL is electrically connected to a selection transistor drive line among the pixel drive lines 10 (see FIG. 2).

The source region of the reset transistor RST is electrically connected to the charge holding region FD of each of the first pixel group 16A and the second pixel group 16B and the gate electrode of each of the three amplification transistors AMP1 to AMP3. The drain region of the reset transistor RST is electrically connected to the power supply line VDD and the drain region of each of the three amplification transistors AMP1 to AMP3. Then, the gate electrode of the reset transistor RST is electrically connected to a reset transistor drive line among the pixel drive lines 10 (see FIG. 2).

When being turned on, the transfer transistor TR transfers the signal charge generated in the photoelectric conversion element PD to the charge holding region FD. When being turned on, the reset transistor RST resets a potential (signal charge) of the charge holding region FD to a potential of the power supply line VDD. The selection transistor SEL controls output timing of the pixel signal from the read circuit 17.

Each of the three amplification transistors AMP1 to AMP3 generates a signal of a voltage corresponding to the level of the signal charge held in the charge holding region FD as the pixel signal. Each of the three amplification transistors AMP1 to AMP3 constitutes a source follower type amplifier, and outputs a pixel signal of a voltage corresponding to the level of the signal charge generated in the photoelectric conversion element PD. When the selection transistor SEL is turned on, each of the three amplification transistors AMP1 to AMP3 amplifies the potential of the charge holding region FD, and outputs a voltage corresponding to the potential to the column signal processing circuit 5 via the vertical signal line (VSL) 11.

While the solid-state imaging device 1A according to the first embodiment is in operation, the signal charge generated in the photoelectric conversion element PD of the pixel 3 is held in the charge holding region FD via the transfer transistor TR of the pixel 3. Then, the signal charge held in the charge holding region FD is read by the read circuit 17 and applied to the gate electrode of each of the three amplification transistors AMP1 to AMP3 of the read circuit 17. A horizontal line selection control signal is supplied from a vertical shift register to the gate electrode of the selection transistor SEL of the read circuit 17. Setting the selection control signal to a high (H) level brings the selection transistor SEL into conduction to allow a current corresponding to the potential of the charge holding region FD, amplified by each of the three amplification transistors AMP1 to AMP3, to flow to the vertical signal line 11. Furthermore, setting a reset control signal to be applied to the gate electrode of the reset transistor RST of the read circuit 17 to the high (H) level brings the reset transistor RST into conduction to reset the signal charge accumulated in the charge holding region FD.

<<Specific Configuration of Solid-State Imaging Device>>

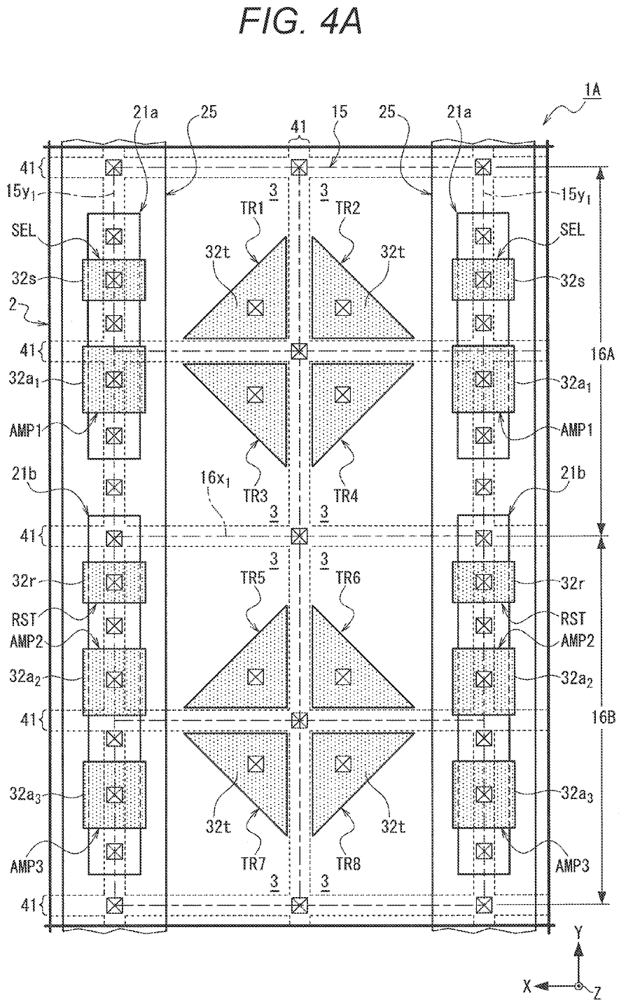

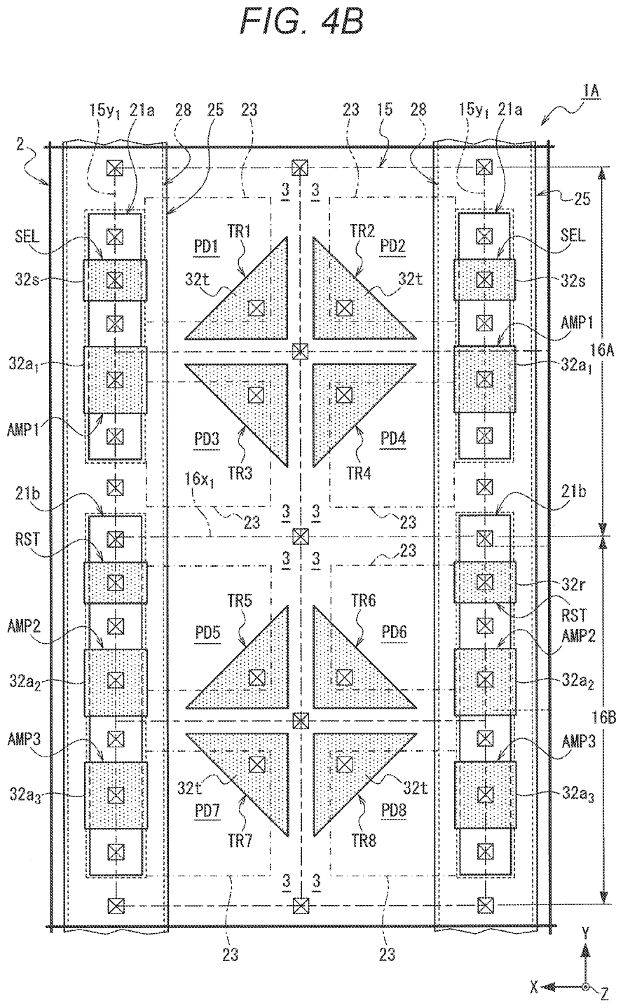

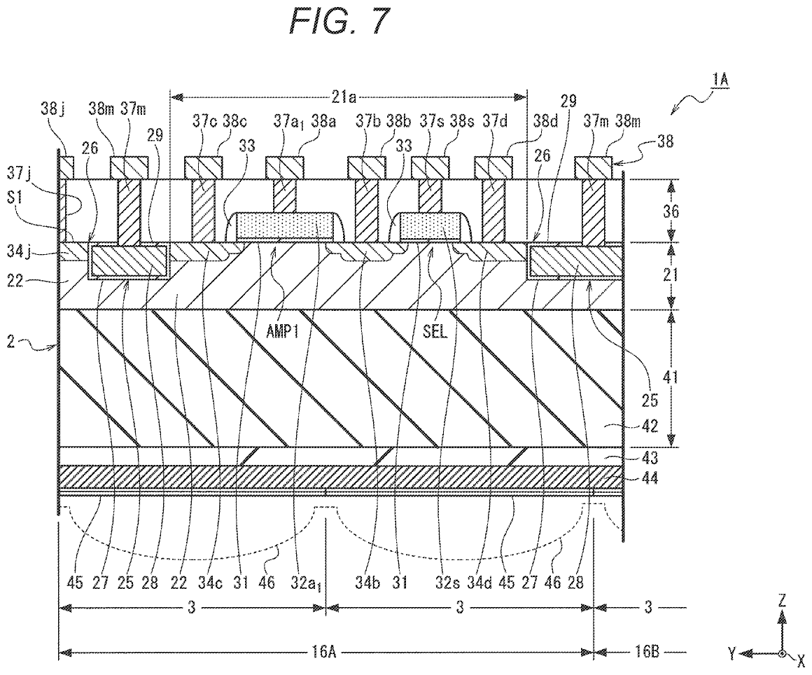

Next, a specific configuration of the semiconductor chip 2 (solid-state imaging device 1A) will be described with reference to FIGS. 4A to 9. Note that illustration of a multilayer wiring layer to be described later is omitted in FIGS. 4A, 4B, 5, and 6 in order to make the drawings easier to see. In addition, in FIGS. 7, 8, and 9, illustration of layers above a wiring layer 38 to be described later is omitted.

<Semiconductor Chip>

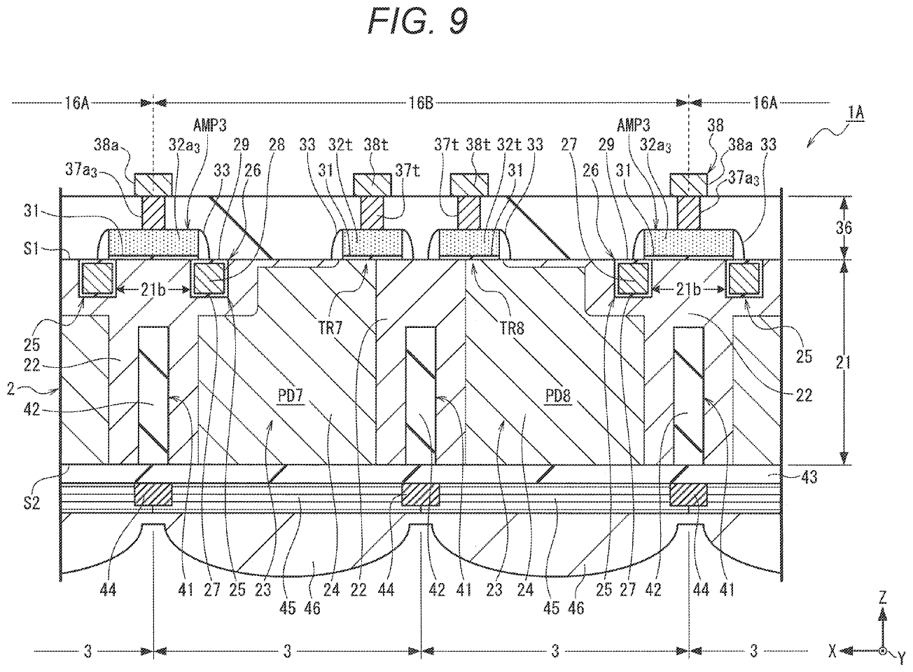

As illustrated in FIG. 9, the semiconductor chip 2 includes a semiconductor layer 21 having a first surface S1 and a second surface S2 located opposite to each other, and a multilayer wiring layer including an insulating layer 36 and a wiring layer 38 provided on the side of the first surface S1 of the semiconductor layer 21. In addition, the semiconductor chip 2 includes, on the side of the second surface S2 of the semiconductor layer 21, a planarization film 43, a light shielding film 44, a color filter 45, and a microlens (on-chip lens) 46 sequentially provided from the side of the second surface S2.

The planarization film 43 is provided on the side of the second surface S2 of the semiconductor layer 21 so as to cover the second surface S2 of the semiconductor layer 21, and planarizes the side of the second surface S2 of the semiconductor layer 21. In the light shielding film 44, a planar pattern in plan view is a lattice-shaped planar pattern so as to partition the adjacent pixels 3.

The color filter 45 and the microlens 46 are provided for every pixel 3. The color filter 45 color-separates incident light incident from the light incidence surface of the semiconductor chip 2. The microlens 46 condenses irradiation light and allows the condensed light to efficiently enter the pixel 3.

Here, the first surface S1 of the semiconductor layer 21 may be also referred to as an element formation surface or main surface, and the second surface S2 may be also referred to as a light incidence surface or back surface. In the solid-state imaging device 1A according to the first embodiment, light incident from the second surface (light incidence surface, back surface) S2 of the semiconductor layer 21 is photoelectrically converted by a photoelectric converter 23 (photoelectric conversion element PD) provided in the semiconductor layer 21.

<Pixel Block>

As illustrated in FIG. 4A, each of the first pixel group 16A and the second pixel group 16B included in the pixel block 15 is disposed adjacent to each other in the Y direction in plan view. Then, as illustrated in FIGS. 4A, 5, and 6, the four pixels 3 included in the first pixel group 16A and the four pixels 3 included in the second pixel group 16B are arranged two by two in each of the X direction and the Y direction in plan view, resulting in a 2×2 layout arrangement. That is, in the pixel region 2A described above, the pixel block 15 having a total of eight pixels 3 included in two pixel groups (16A and 16B) as one unit is repeatedly arranged in each of the X direction and the Y direction.

<Semiconductor Layer>

As illustrated in FIGS. 7 to 9, the semiconductor layer 21 includes an element isolation region 25 and island-shaped element formation regions (active regions) 21a and 21b defined by the element isolation region 25 on the side of the first surface S1. In addition, the semiconductor layer 21 further includes a pixel isolation region 41 on the side of the second surface S2. Furthermore, the semiconductor layer 21 further includes a semiconductor region 22 of p-type as the second conductivity type, and the photoelectric converter 23 (see FIG. 9) surrounded by the p-type semiconductor region 22. The semiconductor layer 21 includes, for example, a p-type single crystal silicon substrate.

<Pixel Isolation Region>

As illustrated in FIGS. 4A, 5, 6, and 9, the pixel isolation region 41 extends from the second surface S2 toward the first surface S1 of the semiconductor layer 21, and electrically and optically isolates the pixels 3 adjacent to each other in the two-dimensional plane. The pixel isolation region 41 has, but not limited to, for example, a trench structure in which an insulating film 42 is embedded in a groove extending from the second surface S2 of the semiconductor layer 21 toward the first surface S1 and is separated from the first surface S1 of the semiconductor layer 21.

As illustrated in FIGS. 4, 5, and 6, the pixel isolation region 41 corresponding to one pixel 3 is an annular planar pattern (ring-shaped planar pattern) having a rectangular planar shape in plan view. Then, the pixel isolation region 41 corresponding to the eight pixels 3 of the pixel block 15 is a composite planar pattern having a lattice-shaped planar pattern in a rectangular annular planar pattern surrounding a periphery of the eight pixels 3 in plan view. That is, the pixel isolation region 41 isolates the side of the second surface S2 of the semiconductor layer 21 for every pixel 3.

<Photoelectric Converter>

As illustrated in FIGS. 4, 5, 6, and 9, the photoelectric converter 23 is provided for every pixel 3. The photoelectric converter 23 includes a semiconductor region 24 of n-type as the first conductivity type. Then, the photoelectric converter 23 constitutes the photoelectric conversion element PD described above. FIG. 9 shows, as an example, the photoelectric converter 23 constituting the photoelectric conversion element PD7 and the photoelectric converter 23 constituting the photoelectric conversion element PD8 among the photoelectric converters 23 constituting the eight photoelectric conversion elements PD1 to PD8, respectively.

<P-Type Semiconductor Region>

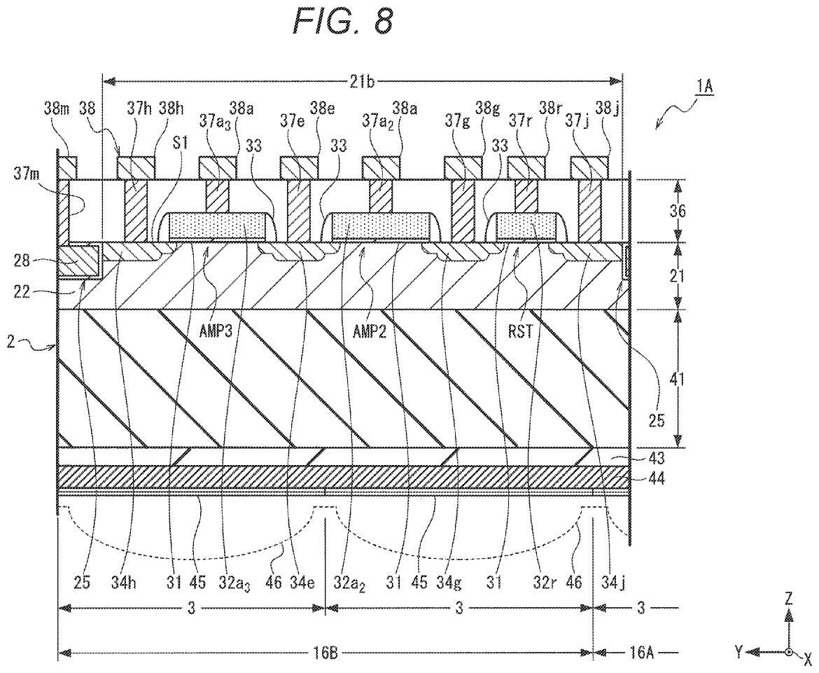

As illustrated in FIGS. 7 and 8, the p-type semiconductor region 22 is provided over two pixels 3 adjacent to each other in the Y direction. In addition, as illustrated in FIG. 9, the p-type semiconductor region 22 is also provided between two photoelectric converters 23 adjacent to each other in the X direction, between the photoelectric converter 23 and the first surface S1 of the semiconductor layer 21, and between the photoelectric converter 23 and the element isolation region 25. Furthermore, as illustrated in FIGS. 7, 8, and 9, the p-type semiconductor region 22 is also provided in the element formation regions 21a and 21b. Then, although not illustrated in detail, the p-type semiconductor region 22 is also provided between two photoelectric converters 23 adjacent to each other in the Y direction. The p-type semiconductor region 22 located between the two photoelectric converters 23 adjacent to each other in each of the X direction and the Y direction is provided from the first surface S1 toward the second surface S2 of the semiconductor layer 21 when described with reference to FIG. 9. The pixel isolation region 41 is included in the p-type semiconductor region 22 and is separated from the photoelectric converter 23 with the p-type semiconductor region 22 interposed therebetween. The p-type semiconductor region 22 includes one semiconductor region or a plurality of semiconductor regions. The p-type semiconductor region 22 and the n-type semiconductor region 24 of the photoelectric converter 23 form a pn junction for every pixel 3.

Note that each of the eight photoelectric conversion elements PD1 to PD8 includes a pn junction constituted by the p-type semiconductor region 22 and the n-type semiconductor region 24 of the photoelectric converter 23 for every pixel 3.

Furthermore, the p-type semiconductor region 22 between the pixel isolation region 41 and the photoelectric converter 23 functions as a pinning layer that surrounds a periphery of the photoelectric converter 23 in plan view and controls generation of dark current.

<Element Isolation Region>

As illustrated in FIGS. 4A and 4B, the element isolation region 25 is disposed in a region including a virtual boundary line 15y₁ between two pixel blocks 15 adjacent to each other in the X direction, along an extending direction of the virtual boundary line 15y₁ (the Y direction). The element isolation region 25 has a predetermined width in the X direction and is arranged for every virtual boundary line 15y₁. That is, although not limited thereto, the element isolation regions 25 are arranged for every pixel block column in which the pixel blocks 15 are repeatedly arranged in the Y direction.

<Element Formation Region>

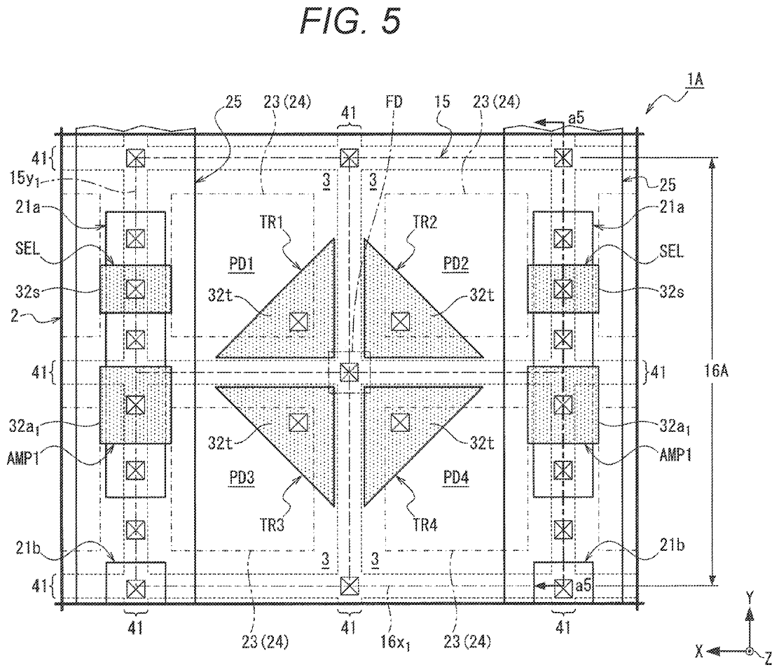

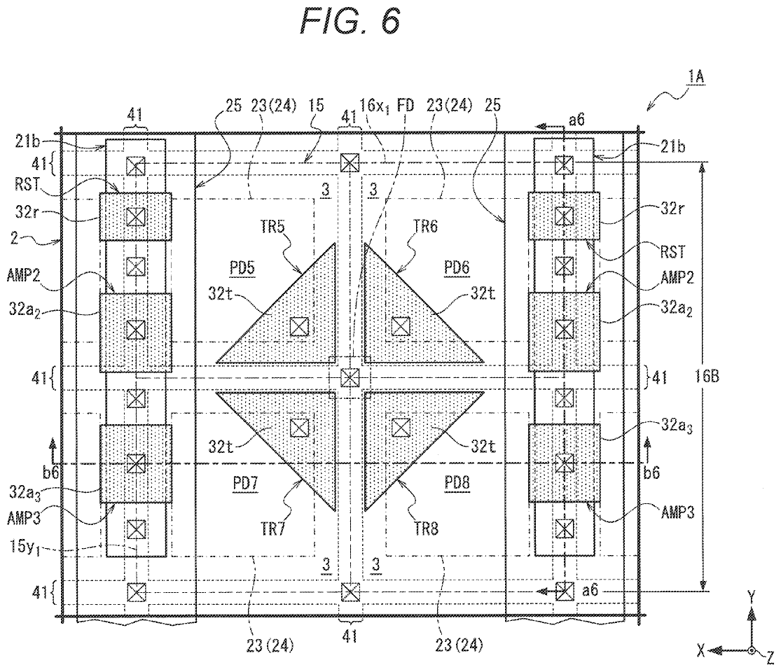

As illustrated in FIGS. 4A and 4B, the element formation regions 21a and 21b defined by the element isolation region 25 are arranged in series at a predetermined interval in the extending direction of the virtual boundary line 15y₁ (the Y direction) in a region including the virtual boundary line 15y₁ between two pixel blocks 15 adjacent to each other in the X direction. Then, each of the element formation regions 21a and 21b has a width in the X direction and extends along the extending direction of the virtual boundary line 15y₁. As illustrated in FIG. 5, the element formation region 21a is disposed along the virtual boundary line 15y₁ in a region including the virtual boundary line 15y₁ between two first pixel groups 16A adjacent to each other in the X direction. Then, the element formation region 21a is surrounded by the element isolation region 25. As illustrated in FIG. 6, the element formation region 21b is disposed along the virtual boundary line 15y₁ in a region including the virtual boundary line 15y₁ between two second pixel groups 16B adjacent to each other in the X direction. Then, the element formation region 21b is surrounded by the element isolation region 25. Each of the element formation regions 21a and 21b has, for example, a rectangular shape (belt shape) in plan view.

Note that, in FIGS. 4A, 4B, 5, and 6, one set of element formation regions 21a and 21b is arranged side by side in the Y direction on both sides in the X direction of the pixel block 15, and one set of element formation regions 21a and 21b corresponds to one pixel block 15.

As illustrated in FIGS. 4A and 5, in the element formation region 21a, one amplification transistor AMP1 and one selection transistor SEL among the pixel transistors included in the read circuit 17 are provided side by side in the Y direction. As illustrated in FIGS. 4A and 6, in the element formation region 21b, two amplification transistors AMP2 and AMP3 and one reset transistor RST among the pixel transistors included in the read circuit 17 are provided side by side in the Y direction.

<Amplification Transistor AMP1 and Selection Transistor SEL>

As illustrated in FIG. 7, the amplification transistor AMP1 includes a gate insulating film 31 provided on the element formation region 21a on the side of the first surface S1 of the semiconductor layer 21, a gate electrode 32a₁ provided on the element formation region 21a with the gate insulating film 31 interposed therebetween, and a side wall spacer 33 provided on a side wall of the gate electrode 32a₁ so as to surround the gate electrode 32a₁. In addition, the amplification transistor AMP1 further includes a channel formation region in which a channel (conduction path) is formed in the p-type semiconductor region 22 immediately below the gate electrode 32a₁, and a pair of main electrode regions 34b and 34c that is provided in the p-type semiconductor region 22 to be separated from each other in a channel length direction (gate length direction) with the channel formation region interposed therebetween and functions as the source region and the drain region. The amplification transistor AMP1 controls a channel formed in the channel formation region by a gate voltage applied to the gate electrode 32a₁.

As illustrated in FIG. 7, the selection transistor SEL includes a gate insulating film 31 provided on the element formation region 21a on the side of the first surface S1 of the semiconductor layer 21, a gate electrode 32s provided on the element formation region 21a with the gate insulating film 31 interposed therebetween, and a side wall spacer 33 provided on a side wall of the gate electrode 32s so as to surround the gate electrode 32s. In addition, the selection transistor SEL further includes a channel formation region in which a channel (conduction path) is formed in the p-type semiconductor region 22 immediately below the gate electrode 32s, and a pair of main electrode regions 34d and 34b that is provided in the p-type semiconductor region 22 to be separated from each other in a channel length direction (gate length direction) with the channel formation region interposed therebetween and functions as the source region and the drain region. The selection transistor SEL controls a channel formed in the channel formation region by a gate voltage applied to the gate electrode 32s.

As illustrated in FIG. 7, the amplification transistor AMP1 and the selection transistor SEL share one main electrode region (source region) 34b of the amplification transistor AMP1 and the other main electrode region (drain region) 34b of the selection transistor SEL.

The main electrode region 34b includes, but not limited to, an extension region including an n-type semiconductor region and formed by self-alignment with the gate electrode 32a₁, an extension region including an n-type semiconductor region and formed by self-alignment with the gate electrode 32s, and a contact region including an n-type semiconductor region having a higher impurity concentration than these extension regions and formed by self-alignment with the side wall spacer 33 of the side wall of each of the gate electrodes 32a₁ and 32s.

The main electrode region 34c includes, but not limited to, an extension region including an n-type semiconductor region and formed by self-alignment with the gate electrode 32a₁ and a contact region including an n-type semiconductor region having a higher impurity concentration than the extension region and formed by self-alignment with the side wall spacer 33 of the side wall of the gate electrodes 32a₁.

The main electrode region 34d includes, but not limited to, an extension region including an n-type semiconductor region and formed by self-alignment with the gate electrode 32s and a contact region including an n-type semiconductor region having a higher impurity concentration than the extension region and formed by self-alignment with the side wall spacer 33 of the side wall of the gate electrodes 32s.

<Amplification Transistors AMP2 to AMP3 and Reset Transistor RST>

As illustrated in FIG. 8, the amplification transistor AMP2 includes a gate insulating film 31 provided on the element formation region 21b on the side of the first surface S1 of the semiconductor layer 21, a gate electrode 32a2 provided on the element formation region 21b with the gate insulating film 31 interposed therebetween, and a side wall spacer 33 provided on a side wall of the gate electrode 32a₂ so as to surround the gate electrode 32a₂. In addition, the amplification transistor AMP2 further includes a channel formation region in which a channel (conduction path) is formed in the p-type semiconductor region 22 immediately below the gate electrode 32a₂, and a pair of main electrode regions 34e and 34g that is provided in the p-type semiconductor region 22 to be separated from each other in a channel length direction (gate length direction) with the channel formation region interposed therebetween and functions as the source region and the drain region. The amplification transistor AMP2 controls a channel formed in the channel formation region by a gate voltage applied to the gate electrode 32a2.

The amplification transistor AMP3 includes a gate insulating film 31 provided on the element formation region 21b on the side of the first surface S1 of the semiconductor layer 21, a gate electrode 32a₃ provided on the element formation region 21b with the gate insulating film 31 interposed therebetween, and a side wall spacer 33 provided on a side wall of the gate electrode 32a3 so as to surround the gate electrode 32a₃. In addition, the amplification transistor AMP3 further includes a channel formation region provided in the p-type semiconductor region 22 immediately below the gate electrode 32a₃, and a pair of main electrode regions 34e and 34h that is provided in the p-type semiconductor region 22 to be separated from each other in a channel length direction (gate length direction) with the channel formation region interposed therebetween and functions as the source region and the drain region. The amplification transistor AMP3 controls a channel formed in the channel formation region by a gate voltage applied to the gate electrode 32aa.

The reset transistor RST includes a gate insulating film 31 provided on the element formation region 21b on the side of the first surface S1 of the semiconductor layer 21, a gate electrode 32r provided on the element formation region 21b with the gate insulating film 31 interposed therebetween, and a side wall spacer 33 provided on a side wall of the gate electrode 32r so as to surround the gate electrode 32r. In addition, the reset transistor RST further includes a channel formation region in which a channel (conduction path) is formed in the p-type semiconductor region 22 immediately below the gate electrode 32r, and a pair of main electrode regions 34j and 34g that is provided in the p-type semiconductor region 22 to be separated from each other in a channel length direction (gate length direction) with the channel formation region interposed therebetween and functions as the source region and the drain region. The reset transistor RST controls a channel formed in the channel formation region by a gate voltage applied to the gate electrode 32r.

As illustrated in FIG. 8, the amplification transistors AMP2 and AMP3 share one main electrode region (source region) 34e of each of the amplification transistors AMP2 and AMP3. The amplification transistor AMP2 and the reset transistor RST share the other main electrode region (drain region) 34g of the amplification transistor AMP2 and the other main electrode region (drain region) 34g of the reset transistor RST.

The main electrode region 34e includes, but not limited to, an extension region including an n-type semiconductor region and formed by self-alignment with the gate electrode 32a₂, an extension region including an n-type semiconductor region and formed by self-alignment with the gate electrode 32a₃, and a contact region including an n-type semiconductor region having a higher impurity concentration than these extension regions and formed by self-alignment with the side wall spacer 33 of the side wall of each of the gate electrodes 32a₂ and 32a₃.

The main electrode region 34g includes, but not limited to, an extension region including an n-type semiconductor region and formed by self-alignment with the gate electrode 32a₂, an extension region including an n-type semiconductor region and formed by self-alignment with the gate electrode 32r, and a contact region including an n-type semiconductor region having a higher impurity concentration than these extension regions and formed by self-alignment with the side wall spacer 33 of the side wall of each of the gate electrodes 32a₂ and 32r.

The main electrode region 34h includes, but not limited to, an extension region including an n-type semiconductor region and formed by self-alignment with the gate electrode 32a₃ and a contact region including an n-type semiconductor region having a higher impurity concentration than the extension region and formed by self-alignment with the side wall spacer 33 of the side wall of the gate electrodes 32a₃.

The main electrode region 34j includes, but not limited to, an extension region including an n-type semiconductor region and formed by self-alignment with the gate electrode 32r and a contact region including an n-type semiconductor region having a higher impurity concentration than the extension region and formed by self-alignment with the side wall spacer 33 of the side wall of the gate electrodes 32r.

<Gate Insulating Film and Gate Electrodes>

The gate insulating film 31 includes, for example, a silicon oxide (SiO₂) film. Each of the gate electrodes 32a₁, 32a₂, 32a₃, 32r, and 32s includes, for example, a polycrystalline silicon film doped with an impurity to make a resistance value lower. The side wall spacer 33 includes, for example, a silicon oxide film.

<Insulating Layer and Wiring Layer>

As illustrated in FIGS. 7 and 8, the respective gate electrodes 32a₁, 32a₂, 32a₃, 32r, and 32s of the amplification transistors AMP1 to AMP3, the selection transistor SEL, and the reset transistor RST are covered with an insulating layer 36 provided on the side of the first surface S1 of the semiconductor layer 21. Then, in the wiring layer 38 on the insulating layer 36, each of wires 38a, 38b, 38c, 38d, 38e, 38g, 38h, 38j, 38m, 38r, and 38s is provided, and a wire 38t illustrated in FIG. 9 is provided.

Each wire in the wiring layer 38 includes, for example, a metal film such as copper (Cu) or an alloy having Cu as a main component. The insulating layer 36 includes, for example, a single layer film of one of a silicon oxide film, a silicon nitride (Si3N4) film, or a silicon carbonitride (SiCN) film, or a multilayer film obtained by layering two or more of these films.

<Connection State>

As illustrated in FIG. 7, the gate electrode 32a₁ of the amplification transistor AMP1 is electrically connected to the wire 38a on the insulating layer 36 via the contact electrode 37a₁ embedded in the insulating layer 36. The gate electrode 32s of the selection transistor SEL is electrically connected to the wire 38s on the insulating layer 36 via a contact electrode 37s embedded in the insulating layer 36.

As illustrated in FIG. 7, the other main electrode region (drain region) 34c of the amplification transistor AMP1 is electrically connected to the wire 38c on the insulating layer 36 via a contact electrode 37c embedded in the insulating layer 36. One main electrode region (source region) 34d of the selection transistor SEL is electrically connected to the wire 38d on the insulating layer 36 via a contact electrode 37d embedded in the insulating layer 36. Then, the main electrode region 34b shared as one main electrode region (source region) of the amplification transistor AMP1 and the other main electrode region (drain region) of the selection transistor SEL is electrically connected to the wire 38b on the insulating layer 36 via a contact electrode 37b embedded in the insulating layer 36.

As illustrated in FIG. 8, the gate electrode 32a₂ of the amplification transistor AMP2 is electrically connected to the wire 38a on the insulating layer 36 via a contact electrode 37a₂ embedded in the insulating layer 36. The gate electrode 32a₃ of the amplification transistor AMP3 is electrically connected to the wire 38a on the insulating layer 36 via a contact electrode 37a₃ embedded in the insulating layer 36. The gate electrode 32r of the reset transistor RST is electrically connected to the wire 38r on the insulating layer 36 via a contact electrode 37r embedded in the insulating layer 36.

As illustrated in FIG. 8, the main electrode region 34e shared as one main electrode region (source region) of each of the amplification transistors AMP2 and AMP3 is electrically connected to the wire 38e on the insulating layer 36 via a contact electrode 37e embedded in the insulating layer 36. The main electrode region 34g shared as the other main electrode region (drain region) of the amplification transistor AMP2 and the other main electrode region (drain region) of the reset transistor RST is electrically connected to the wire 38g on the insulating layer 36 via a contact electrode 37g embedded in the insulating layer 36. The other main electrode region 34h of the amplification transistor AMP3 is electrically connected to the wire 38h on the insulating layer 36 via a contact electrode 37h embedded in the insulating layer 36. Then, the other main electrode region (drain region) 34j of the reset transistor RST is electrically connected to the wire 38j on the insulating layer 36 via a contact electrode 37j embedded in the insulating layer 36.

Note that, although not illustrated in detail, the wire 38a is routed over the amplification transistors AMP1 to AMP3 in plan view, and is electrically connected to the respective gate electrodes 32a₁ to 32a₃ of the amplification transistors AMP1 to AMP3. Then, the wire 38a is electrically connected to the wire 38g and the two charge holding regions FD. In addition, the wire 38b is electrically connected to the wire 38e. Furthermore, the wire 38c is electrically connected to the wire 38j and the power supply line VDD. Then, the wire 38d is electrically connected to a vertical signal line 11.

<Transfer Transistor>

As illustrated in FIGS. 4A, 5, 6, and 9, the transfer transistor TR (TR1 to TR8) is provided for every pixel 3 (photoelectric converter 23) on the side of the first surface S1 of the semiconductor layer 21. FIG. 9 shows two transfer transistors TR7 and TR8 among the eight transfer transistors TR as an example.

As illustrated in FIG. 9, the transfer transistor TR (TR7, TR8) includes the gate insulating film 31 provided on the side of the first surface S1 of the semiconductor layer 21, a gate electrode 32t provided on the side of the first surface S1 of the semiconductor layer 21 with the gate insulating film 31 interposed therebetween, and the side wall spacer 33 provided on a side wall of the gate electrode 32t so as to surround the gate electrode 32t. Furthermore, the transfer transistor TR includes the channel formation region in which a channel is formed in the p-type semiconductor region 22 immediately below the gate electrode 32t, the photoelectric converter 23 functioning as a source region, and the charge holding region FD (see FIG. 6) functioning as the drain region. The gate electrode 32r is formed, for example, in the same process as the gate electrodes (32a₁, 32a₂, 32a₃, 32s, and 32r) of the above-described pixel transistors (AMP1 to AMP3, SEL, and RST), and includes a polycrystalline silicon film doped with an impurity to make a resistance value lower, in a similar manner to the gate electrodes of the pixel transistors.

The transfer transistor TR is a field effect transistor, and includes, for example, a MOSFET in a similar manner to the above-described pixel transistors. The transfer transistor TR may include a MISFET.

As illustrated in FIGS. 6 and 9, the gate electrodes 32t of the respective transfer transistors TR of the four pixels 3 included in the second pixel group 16B are disposed to be biased to a corner from a center of each pixel 3 in plan view. Then, the gate electrodes 32t of the respective transfer transistors TR of the four pixels 3 are disposed to be biased toward a central portion surrounded by the four pixels 3 arranged in 2×2. That is, the gate electrodes 32t of the respective transfer transistors TR of the four pixels 3 are adjacent to each other in each of the X direction and the Y direction. Then, the above-described charge holding region FD is provided in a surface layer of the semiconductor layer 21 on the side of the first surface S1 in a region surrounded by the gate electrodes 32t of the respective transfer transistors TR of the four pixels 3.

Although not illustrated in detail, the charge holding region FD is provided in the p-type semiconductor region 22 and includes an n-type semiconductor region. Then, the charge holding region FD overlaps the pixel isolation region 41 in plan view. That is, the charge holding region FD is disposed in a region where the pixel isolation region 41 extending in the X direction and the pixel isolation region 41 extending in the Y direction intersect. The charge holding region FD according to the first embodiment is provided, but not limited to, in a central region surrounded by four gate electrodes 32t as illustrated in FIG. 6.

Note that the gate electrodes 32t of the four transfer transistors TR and the charge holding region FD included in the first pixel group 16A is basically similar in configuration to the gate electrodes 32t of the four transfer transistors TR and the charge holding region FD included in the second pixel group 16B.

As illustrated in FIG. 6, in the four pixels 3 included in the second pixel group 16B, the p-type semiconductor region 22, the photoelectric converter 23, and the gate electrode 32t of the transfer transistor TR are configured in an inversion pattern in which a boundary between the two pixels 3 adjacent to each other in the X direction and a boundary between the two pixels 3 adjacent to each other in the Y direction are set as inversion axes.

Furthermore, as illustrated in FIG. 5, in the four pixels 3 included in the first pixel group 16A, the p-type semiconductor region 22, the photoelectric converter 23, and the gate electrode 32t of the transfer transistor TR are also configured in an inversion pattern in which the boundary between the two pixels 3 adjacent to each other in the X direction and the boundary between the two pixels 3 adjacent to each other in the Y direction are set as inversion axes.

<Connection Form>

As illustrated in FIG. 9, the gate electrode 32t of each of the two transfer transistors TR7 and TR8 is electrically connected to the individual wire 38t on the insulating layer 36 via a contact electrode 37t individually embedded in the insulating layer 36. Furthermore, although not illustrated in detail, the gate electrode of each of the transfer transistors TR1 to TR6 is also electrically connected to the individual wire on the insulating layer 36 via a contact electrode individually embedded in the insulating layer 36, in a similar manner to the two transfer transistors TR7 and TR8.

Note that, although not illustrated, each of the two charge holding regions FD included in the pixel block 15 is electrically connected to the gate electrode 32a₁ to 32a₃ of the respective three amplification transistors AMP 1 to 3 and the main electrode region 34g of the reset transistor RST via a contact electrode embedded in the insulating layer 36 and a wire on the insulating layer 36.

<Specific Configuration of Element Isolation Region>

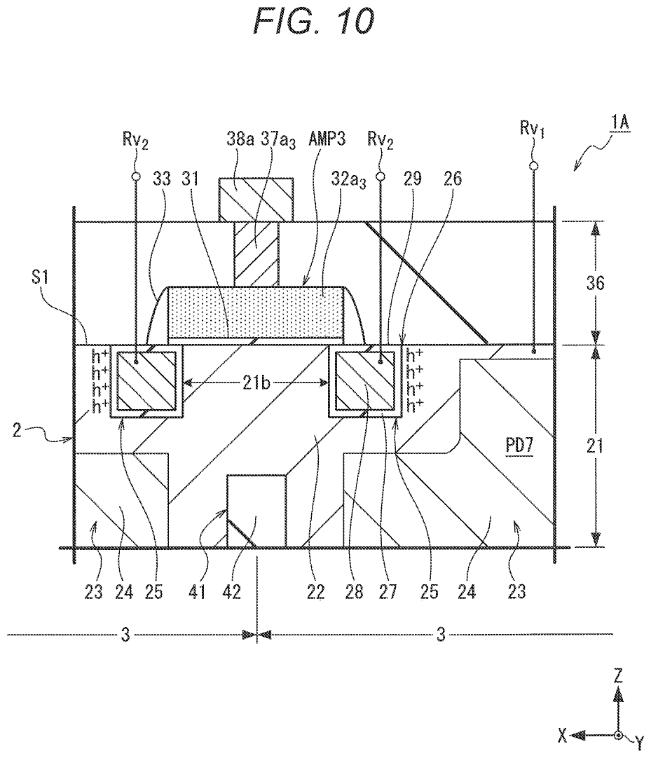

As illustrated in FIGS. 9 and 10, the amplification transistor AMP3 is adjacent to the photoelectric converter 23 across the element isolation region 25. The element isolation region 25 includes a groove (recess) 26 provided on the side of the first surface S1 of the semiconductor layer 21, a conductive film 28 provided in the groove 26 with the first insulating film 27 interposed therebetween, and a second insulating film 29 provided on the side of the first surface S1 of the semiconductor layer 21 so as to overlap the conductive film 28 in plan view. The element isolation region 25 is provided in the surface layer of the first surface S1 of the semiconductor layer 21. Then, the element isolation region 25 has a thickness in the thickness direction of the semiconductor layer 21 (Z direction) and is separated from the second surface S2. That is, the element isolation region 25 has a shallow trench isolation (STI) structure.

The first insulating film 27 is provided along a wall surface and a bottom surface in the groove 26, and is interposed between the semiconductor layer 21 and the conductive film 28. That is, the first insulating film 27 electrically isolates the semiconductor layer 21 from the conductive film 28.

As illustrated in FIGS. 9 and 10, the second insulating film 29 covers the conductive film 28. In other words, an upper surface of the conductive film 28 located on the side of the first surface S1 of the semiconductor layer 21 is covered with the second insulating film 29. Then, the second insulating film 29 is interposed between the gate electrode 32a₃ and the conductive film 28 of the element isolation region 25.

The second insulating film 29 is provided in a layer different from the gate insulating film 31. Then, the second insulating film 29 is provided between the conductive film 28 and the side wall spacer 33.

Each of the first insulating film 27 and the second insulating film 29 includes a thermal oxide film or a deposited film. For example, the first insulating film 27 includes a silicon oxide film by thermal oxidation. The second insulating film 29 includes a silicon oxide film by deposition. The second insulating film 29 has, but not limited to, a film thickness substantially equal to a film thickness of the gate insulating film 31, for example.

As illustrated in FIG. 4B, the conductive film 28 is provided, but not limited to, in the entire region of the element isolation region 25 in plan view. Then, each of the element formation regions 21a and 21b is surrounded by the conductive film 28. In this manner, by surrounding a periphery of each of the element formation regions 21a and 21b with the conductive film 28, the conductive film 28 can be included (disposed) in the element isolation region 25 between the pixel transistors (the amplification transistor AMP1 and the selection transistor SEL) provided in the element formation region 21a and the photoelectric converter 23. In addition, the conductive film 28 can be included (disposed) in the element isolation region 25 between the pixel transistors (the amplification transistors AMP1 and AMP2 and the reset transistor RST) provided in the element formation region 21b and the photoelectric converter 23.

As illustrated in FIGS. 7 and 8, the conductive film 28 of the element isolation region 25 is electrically connected to the wire 38m on the insulating layer 36 via a contact electrode 37m embedded in the insulating layer 36. A power supply potential (power supply voltage) is applied to the wire 38m. That is, the conductive film 28 is electrically connected to the wire 38m to which the power supply potential is applied, and the potential is fixed to the power supply potential supplied from the wire 38m.

As illustrated in FIG. 10, a first reference potential Rv₁ is applied to the p-type semiconductor region 22 as a power supply potential. Then, a second reference potential Rv₂ is applied to the conductive film 28 of the element isolation region 25 as a power supply potential. In the first embodiment, although not limited thereto, for example, 0 V is applied to the p-type semiconductor region 22 as the first reference potential Rv₁, and for example, 0 V is applied as the second reference potential Rv₂ to the conductive film 28 of the element isolation region 25. The application of the first reference potential Rv₁ to the conductive film 28 is held during photoelectric conversion by the photoelectric conversion element PD or during driving of the pixel transistors such as the amplification transistors AMP1 to AMP3, the selection transistor SEL, and the reset transistor RST.

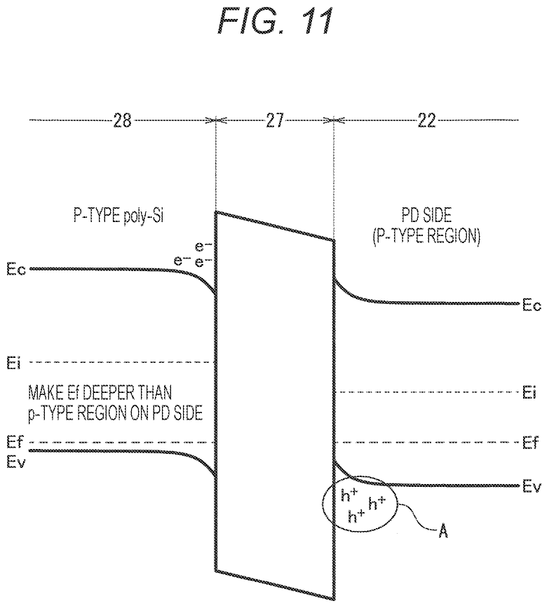

The conductive film 28 includes, but not limited to, a conductive material having a deeper Fermi level than the p-type semiconductor region 22. In the first embodiment, for example, as illustrated in FIG. 11, p-type polycrystalline silicon (p-type Poly-Si) having an impurity concentration higher than an impurity concentration higher of the p-type semiconductor region 22 is used as the conductive material of the conductive film 28. In FIG. 11, Ec represents conductor end energy, Ei represents an intrinsic Fermi level, Ff represents a Fermi level, and Ev represents valence band end energy.

<Orientation of Pixel Transistor Region>

As illustrated in FIGS. 6 and 9, the amplification transistor AMP3 is provided in the element formation region 21b in an orientation in which the channel formation region (p-type semiconductor region 22) immediately below the gate electrode 32a₃ of the amplification transistor AMP3 is adjacent to the photoelectric converter 23 across the element isolation region 25 in plan view. In other words, the amplification transistor AMP3 is provided in the element formation region 21b in an orientation in which the photoelectric converter 23 is located outside the gate electrode 32a₃ in a gate width direction (the X direction in FIGS. 6 and 9). In still other words, the amplification transistor AMP3 is provided in the element formation region 21b in an orientation in which the channel formation region immediately below the gate electrode 32a₃ and the pair of main electrode regions 34e and 34h functioning as the source region and the drain region are adjacent to the photoelectric converter 23 across the element isolation region 25. Then, the gate electrode 32a₃ of the amplification transistor AMP3 is provided over the element formation region 21b and the element isolation region 25 in the gate width direction of the gate electrode 32a₃, and has an end in the gate width direction overlapping the element isolation region 25 in plan view.

Here, the gate width direction is a direction of a gate width (Wg) of the gate electrode. The gate width direction is also a direction of a channel width (W) of the channel formation region sandwiched between the source region and the drain region. Then, the gate length direction is a direction of a gate length (Lg) of the gate electrode, and is also a direction of a channel length (L) of the channel formation region sandwiched between the source region and the drain region.

Note that, although not shown in a sectional view, similarly to the amplification transistor AMP3, each of the amplification transistor AMP2 and the reset transistor RST is also provided in the element formation region 21b in an orientation in which each channel formation region (p-type semiconductor region 22) is adjacent to the photoelectric converter 23 across the element isolation region 25, as illustrated in FIG. 6. Then, the respective gate electrodes 32a₂ and 32r of the amplification transistor AMP2 and the reset transistor RST are also provided over the element formation region 21b and the element isolation region 25 in each gate width direction (X direction in FIG. 7), and have an end in each gate width direction overlap the element isolation region 25.

Furthermore, although not shown in a sectional view, in a similar manner to the amplification transistor AMP3, each of the amplification transistor AMP1 and the selection transistor SEL is also provided in the element formation region 21a in an orientation in which each channel formation region (p-type semiconductor region 22) is adjacent to the photoelectric converter 23 across the element isolation region 25, as illustrated in FIG. 5. Then, the respective gate electrodes 32a₁ and 32s of the amplification transistor AMP1 and the selection transistor SEL are also disposed over the element formation region 21b and the element isolation region 25 in each gate width direction (X direction in FIG. 5), and have an end in each gate width direction overlap the element isolation region 25.

In the solid-state imaging device 1A having the above configuration, incident light is emitted from the microlens 46 of the semiconductor chip 2, the emitted incident light sequentially passes through the microlens 46 and the color filter 45, and the transmitted light is photoelectrically converted by the photoelectric converter 23 to generate a signal charge. Then, the generated signal charge is output as a pixel signal by the vertical signal line 11 (see FIG. 2) formed in the multilayer wiring layer via the transfer transistor TR and the read circuit 17 formed on the side of the first surface S1 of the semiconductor layer 21.

Here, in the first embodiment, each of the photoelectric converter 23 and the charge holding region FD includes an n-type semiconductor region. Therefore, in the first embodiment, carriers as signal charges held in the charge holding region FD are electrons (e⁻).

<<Main Effects of First Embodiment>>

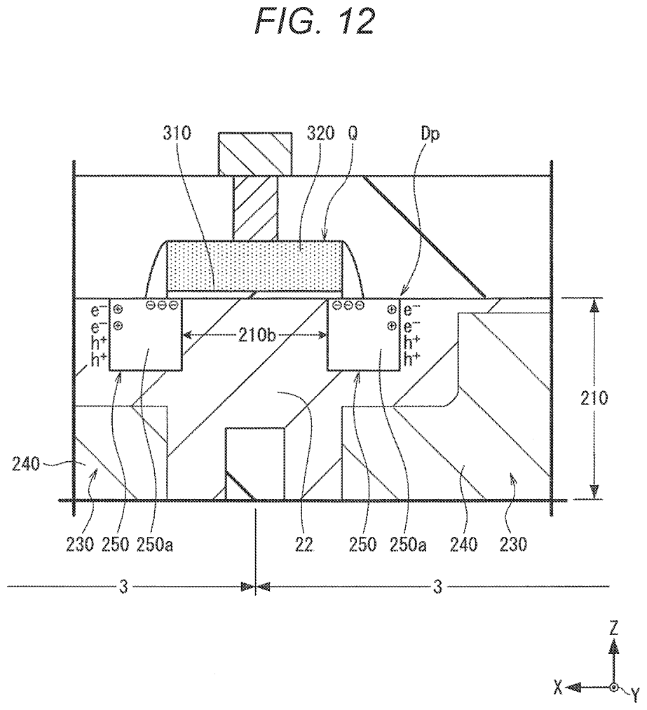

Next, a main effect of the first embodiment will be described while being compared with the element isolation region of a comparative example illustrated in FIG. 12. FIG. 12 is a sectional view of a main part of a solid-state imaging device of the comparative example.

As illustrated in FIG. 12, in the solid-state imaging device of the comparative example, a pixel transistor Q that is a field effect transistor is provided in an element formation region 210b defined by an element isolation region 250 on the side of a first surface of a semiconductor layer 210. The pixel transistor Q includes a gate electrode 320 provided on the element formation region 210b of the semiconductor layer 210 with a gate insulating film 310 interposed therebetween, and a pair of main electrode regions (not shown) provided apart from each other with a channel formation region immediately below the gate electrode 320 interposed therebetween and functioning as the source region and the drain region.

As illustrated in FIG. 12, the pixel transistor Q is provided adjacent to a photoelectric converter 230 on the side of the first surface of the semiconductor layer 210 across the element isolation region 250. Then, the element isolation region 250 has an STI structure in which only an insulating film 250a is embedded in a groove of the semiconductor layer 210.

In this manner, in a case of the element isolation region 250 in which only the insulating film 250a is embedded in the groove of the semiconductor layer 210, a dielectric polarization Dp of the element isolation region 250 is generated as illustrated in FIG. 12 by a fringe electric field from the gate electrode 320 when the pixel transistor Q is driven. As a result, electrons (e⁻) are induced at an interface between the side of the photoelectric converter 230 of the element isolation region 250 and the semiconductor layer 210 (p-type semiconductor region 220), and pinning at an end of the element isolation region 250 (photoelectric converter 230 side of the element isolation region 250) is released, and thus, white spot and dark current characteristics are deteriorated. There is a possibility that the deterioration of the white spot and dark current characteristics becomes more remarkable as a width of the element isolation region 250 is narrowed due to miniaturization of the pixel 3.

On the other hand, in the solid-state imaging device 1A according to the first embodiment, as illustrated in FIG. 10, the amplification transistor AMP3 as a field effect transistor is provided on the first surface S1 of the semiconductor layer 21 so as to be adjacent to the photoelectric converter 23 across the element isolation region 25. Then, the element isolation region 25 according to the first embodiment includes the conductive film 28 unlike the element isolation region 250 of the comparative example illustrated in FIG. 12. That is, as illustrated in FIGS. 4B and 9, the amplification transistor AMP3 is adjacent to the photoelectric converter 23 across the conductive film 28 of the element isolation region 25. As a result, by applying the second reference potential Rv₂ of, for example, 0 V to the conductive film 28 to fix the potential of the conductive film 28, the fringe electric field from the gate electrode 32a₃ of the amplification transistor AMP1 is shielded by the conductive film 28 of the element isolation region 25. Therefore, as illustrated in FIG. 10, electrons (e⁻) are not induced at the interface between the side of the photoelectric converter 23 of the element isolation region 25 and the semiconductor layer 21 (p-type semiconductor region 22), and pinning at an end of the element isolation region 25 (the side of the photoelectric converter 230 of the element isolation region 250) can be secured. Therefore, the solid-state imaging device 1A according to the first embodiment can suppress deterioration of white spot and dark current characteristics. The effect of suppressing the deterioration of the white spot and dark current characteristics becomes more remarkable as a width of the element isolation region 25 is narrowed due to the miniaturization of the pixel 3.

In addition, the element isolation region 25 according to the first embodiment further includes the second insulating film 29 overlapping the conductive film 28 in plan view on the side of the first surface S1 of the semiconductor layer 21. Accordingly, electrical conduction between the gate electrode 32a₃ of the amplification transistor AMP3 and the conductive film 28 of the element isolation region 25 can be prevented. Therefore, the solid-state imaging device 1A according to the first embodiment can suppress deterioration of white spot and dark current characteristics, and can prevent electrical conduction between the gate electrode 32a₃ of the amplification transistor AMP3 and the conductive film 28 of the element isolation region 25.

Since at least the second insulating film 29 is interposed between the gate electrode 32a₃ of the amplification transistor AMP3 and the conductive film 28 of the element isolation region 25, insulation resistance between the gate electrode 32a₃ of the amplification transistor AMP3 and the conductive film 28 of the element isolation region 25 can be secured. Then, as in the first embodiment, since the conductive film 28 is covered with the second insulating film 29, the insulation resistance between the gate electrode 32a₃ of the amplification transistor AMP3 and the conductive film 28 of the element isolation region 25 can be further enhanced.

In addition, the amplification transistor AMP3 according to the first embodiment is disposed in the element formation region 21b in an orientation in which the channel formation region immediately below the gate electrode 32a₃ is adjacent to the photoelectric converter 23 across the element isolation region 25. In a case of such an arrangement, the fringe electric field from the gate electrode 32a₃ easily spreads toward the photoelectric converter 23 of the element isolation region 25 when the amplification transistor AMP3 is driven. Therefore, the configuration in which the fringe electric field from the gate electrode 32a₃ of the amplification transistor AMP3 is shielded by the conductive film 28 of the element isolation region 25 is particularly useful in a case where the channel formation region of the amplification transistor AMP3 is adjacent to the photoelectric converter 23 across the element isolation region 25 as in the first embodiment.

Note that, each of the amplification transistors AMP1 and AMP2, the selection transistor SEL, and the reset transistor RST is also disposed in each of the element formation regions 21a and 21b in an orientation in which the channel formation region immediately below the gate electrodes (32a1, 32a2, 32s, and 32r) is adjacent to the photoelectric converter 23 across the element isolation region 25. A fringe electric field from the gate electrodes (32a₁, 32a₂, 32r, and 32s) of these pixel transistors (AMP1, AMP2, SEL, and RST) can also be shielded by the conductive film 28 of the element isolation region 25. Therefore, even when the pixel transistors (AMP1, AMP2, AMP3, SEL, and RST) included in the read circuit 17 are disposed around the photoelectric converter 23 in plan view, pinning at the end of the element isolation region 25 can be secured, and deterioration of white spot and dark current characteristics can be suppressed. That is, the present technology is useful in a case where at least one of the plurality of pixel transistors included in the read circuit 17 is adjacent to the photoelectric converter 23 across the element isolation region 25.

In addition, in the first embodiment, the conductive film 28 of the element isolation region 25 includes p-type polycrystalline silicon having an impurity concentration higher than the impurity concentration of the p-type semiconductor region 22 as a conductive material having a deeper Fermi level than the p-type semiconductor region 22. Therefore, due to modulation of a band structure, holes (h⁺) are accumulated at the interface between the side of the photoelectric converter 23 of the element isolation region 25 and the semiconductor layer 21 (p-type semiconductor region 22) as illustrated in A of FIG. 11, and pinning at the end of the element isolation region 25 can be improved. As a result, the concentration of the p-type semiconductor region 22 in the photoelectric conversion region can be reduced, or the width of the p-type semiconductor region 22 between the element isolation region 25 and the photoelectric converter 23 can be reduced. Therefore, the planar size of the photoelectric converter 23 can be increased in the same pixel size, and a saturation signal amount Qs can be improved.

Note that, as illustrated in FIG. 4B, it is preferable to provide the conductive film 28 in the entire region of the element isolation region 25. However, the conductive film 28 may be selectively provided at least in the element isolation region 25 between the photoelectric converter 23 and the pixel transistor (AMP1, AMP2, AMP3, RST, SEL) disposed around the photoelectric converter 23. In short, it is sufficient that the conductive film 28 is provided at least in the element isolation region 25 between the photoelectric converter 23 and the pixel transistor (AMP1, AMP2, AMP3, RST, SEL).

Note that, in the first embodiment, the solid-state imaging device 1A including the pixel isolation region 41 having the trench structure has been described. However, the present technology is not limited to the solid-state imaging device 1A according to the first embodiment. For example, the present technology can also be applied to a solid-state imaging device including a pixel isolation region having an impurity diffusion structure including a semiconductor region extending from the second surface S2 of the semiconductor layer 21 toward the first surface S1.

Furthermore, in the first embodiment, a case where the solid-state imaging device 1A is mounted on the semiconductor chip 2 has been described. However, the semiconductor chip 2 is formed by individually dividing a plurality of chip formation regions set in the semiconductor wafer. Therefore, the solid-state imaging device 1A is mounted on a semiconductor wafer before the semiconductor wafer is divided into individual semiconductor chips.

<<Modifications>>

<First Modification>

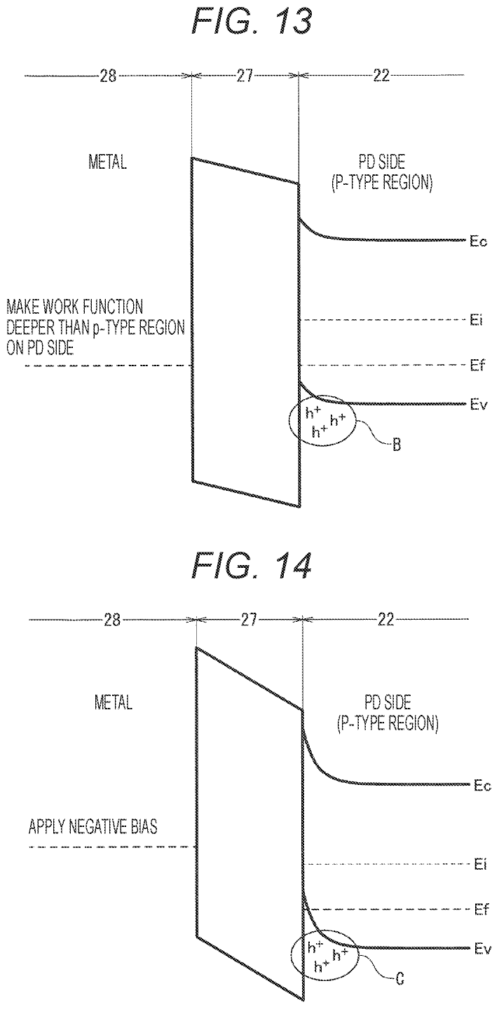

In the first embodiment, a case has been described where p-type polycrystalline silicon (p-type Poly-Si) having a lower Fermi level than the p-type semiconductor region 22 is used as the conductive material included in the conductive film 28 of the element isolation region 25. However, the present technology is not limited to p-type polycrystalline silicon as the conductive material included in the conductive film 28. For example, as the conductive material included in the conductive film 28 of the element isolation region 25, a metal having a deeper work function than the p-type semiconductor region 22 can be used as illustrated in FIG. 13. Examples of the metal include, but not limited to, nickel (Ni) (5.1 eV to 5.2 eV), nickel silicide (NiSi), and platinum (Pt). In a first modification, although not limited thereto, for example, 0 V is applied to the p-type semiconductor region 22 as the first reference potential Rv₁, and 0 V is applied as the second reference potential Rv₂ to the conductive film 28 of the element isolation region 25 with reference to FIG. 10 in a similar manner to the first embodiment.

In this manner, in the first modification in which a metal having a deeper work function than the p-type semiconductor region 22 is used as the conductive material included in the conductive film 28 of the element isolation region 25, holes (h⁺) are accumulated at the interface between the side of the photoelectric converter 23 of the element isolation region 25 and the semiconductor layer 21 (p-type semiconductor region 22) due to the modulation of the band structure as illustrated in B of FIG. 13, and pinning at the end of the element isolation region 25 can be improved. As a result, in the first modification, the concentration of the p-type semiconductor region 22 in the photoelectric conversion region can be reduced, or the width of the p-type semiconductor region 22 between the element isolation region 25 and the photoelectric converter 23 can be reduced. Therefore, the saturation signal amount Qs can be improved.

<Second Modification>

As the conductive material included in the conductive film 28 of the element isolation region 25, a case of using p-type polycrystalline silicon having a deeper Fermi level than the p-type semiconductor region 22 has been described in the first embodiment, and a case of using a metal material having a deeper work function than the p-type semiconductor region 22 has been described in the first modification. However, the present technology is not limited to the conductive materials according to the first embodiment and the first modification. In the second modification, referring to FIG. 10, a negative potential lower than the first reference potential Rv₁ applied to the p-type semiconductor region 22 is applied to the conductive film 28 of the element isolation region 25 as the second reference potential Rv₂. For example, 0 V is applied as the first reference potential Rv₁ to the p-type semiconductor region 22, and −1.2 V is applied as the second reference potential RV₂ to the conductive film 28 of the element isolation region 25. By applying the negative potential to the conductive film 28 of the element isolation region 25 in this manner, as illustrated in C of FIG. 14, holes (h⁺) are accumulated at the interface between the side of the photoelectric converter 23 of the element isolation region 25 and the semiconductor layer 21 (p-type semiconductor region 22). As long as the holes (h⁺) can be sufficiently accumulated at the interface, a Fermi level Ef of the conductive material included in the conductive film 28 of the element isolation region 25 is not limited. That is, by applying the second reference potential RV₂ having a negative potential lower than the first reference potential Rv₁ applied to the p-type semiconductor region 22 to the conductive film 28 of the element isolation region 25, the material of the conductive film 28 of the element isolation region 25 does not need to be limited. Therefore, by applying the second reference potential Rv₂ having a negative potential lower than the first reference potential Rv₁ applied to the p-type semiconductor region 22 to the conductive film 28 of the element isolation region 25, the saturation signal amount Qs can be improved in a similar manner to the first embodiment and the first modification without limiting the conductive material included in the conductive film 28 of the element isolation region 25.

<Third Modification>

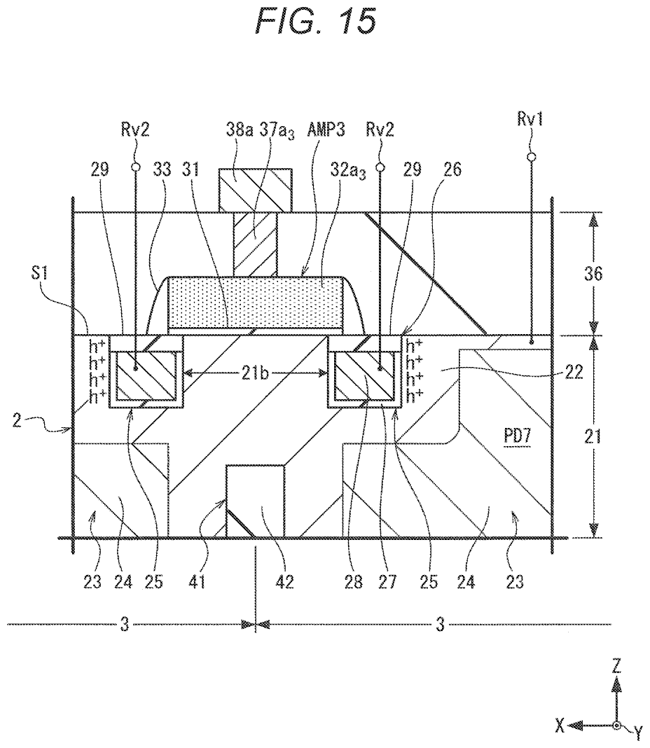

In the first embodiment, a case has been described where the second insulating film 29 of the element isolation region 25 has a film thickness substantially equal to the film thickness of the gate insulating film 31. However, the film thickness of the second insulating film 29 is not limited to the film thickness in the first embodiment. For example, as illustrated in FIG. 15, the film thickness of the second insulating film 29 may be larger than the film thickness of the gate insulating film 31. In a case of a third modification, it is possible to further reduce an influence of the fringe electric field from the gate electrode 32a₃ on the interface between the side of the photoelectric converter 23 of the element isolation region 25 and the semiconductor layer 21 (p-type semiconductor region 22) when the amplification transistor AMP3 is driven.

In the second insulating film 29, the film thickness of a portion interposed between the gate electrode 32a₃ of the amplification transistor AMP3 and the conductive film 28 of the element isolation region 25 may be selectively larger than the film thickness of the gate insulating film 31, or the entire film thickness may be larger than the film thickness of the gate insulating film 31.

Note that it is a matter of course that a similar effect can be obtained by increasing the film thickness of the second insulating film 29 of the element isolation region 25 than the film thickness of the gate insulating film 31 of the other pixel transistors (AMP1, AMP2, RST, and SEL).

### Second Embodiment

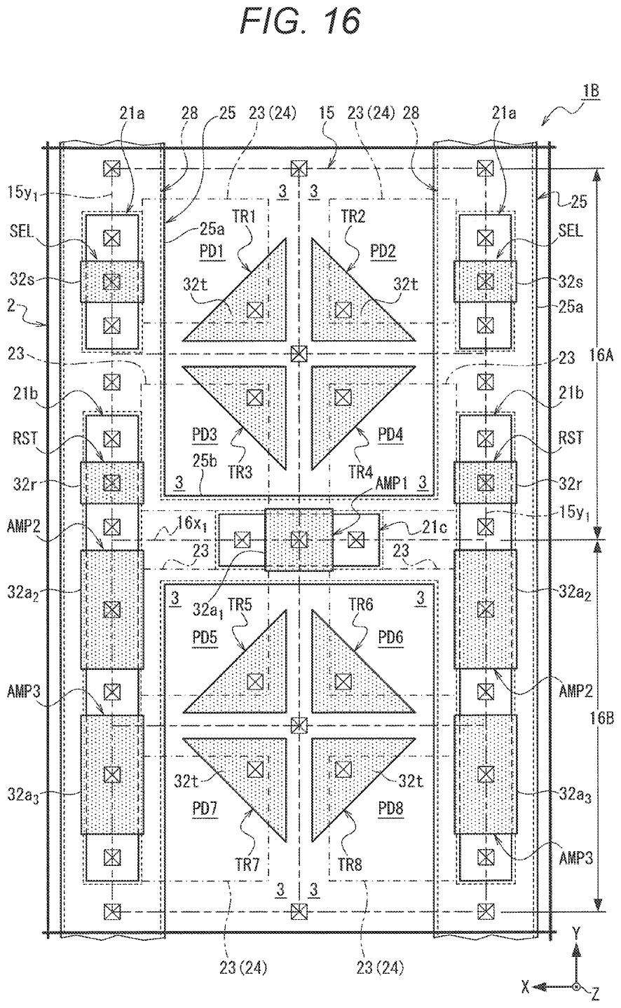

As illustrated in FIG. 16, a solid-state imaging device 1B according to a second embodiment of the present technology basically is basically similar in configuration to the solid-state imaging device 1A according to the first embodiment, and the planar pattern of the element isolation region and the planar layout of the pixel transistors are different.

That is, as illustrated in FIG. 16, the element isolation region 25 according to the second embodiment has a planar pattern including a first portion 25a disposed along the extending direction of the virtual boundary line 15y₁ (Y direction) in a region including the virtual boundary line 15y₁ between two pixel blocks 15 adjacent to each other in the X direction, and a second portion 25b disposed along an extending direction of a virtual boundary line 16x₁ (X direction) in a region including the virtual boundary line 16x₁ between the first pixel group 16A and the second pixel group 16B of the pixel block 15. Then, in the first portion 25a of the element isolation region 25, in a similar manner to the first embodiment, one set of element formation regions 21a and 21b is disposed along the extending direction of the virtual boundary line 15y₁. Then, an island-shaped element formation region 21c extending along the extending direction of the virtual boundary line 16x₁ is disposed in the second portion 25b of the element isolation region 25. Although not illustrated in detail, the element formation region 21c is defined by the element isolation region 25 on the side of the first surface S1 of the semiconductor layer 21, in a similar manner to the element formation regions 21a and 21b illustrated in FIGS. 7 to 9. Then, as illustrated in FIG. 16, the element formation region 21c is also surrounded by the conductive film 28 of the element isolation region 25 in a similar manner to the element formation regions 21a and 21b.

As illustrated in FIG. 16, in the element formation region 21a according to the second embodiment, only one selection transistor SEL is provided, unlike the first embodiment. Then, in the element formation region 21b according to the second embodiment, two amplification transistors AMP2 and AMP3 and one reset transistor RST are provided side by side in the Y direction in a similar manner to the first embodiment. Then, one amplification transistor AMP1 is provided in the element formation region 21c according to the second embodiment. The amplification transistor AMP1 according to the second embodiment is provided in the element formation region 21c in an orientation in which a pair of main electrode regions functioning as the source region and the drain region is aligned along the X direction on both sides of the channel formation region immediately below the gate electrode 32a₁.

In the second embodiment, since the amplification transistor AMP1 is provided in the element formation region 21c, a length of the element formation region 21a in the Y direction is shorter than the length of the element formation region 21a according to the first embodiment. In addition, in the second embodiment, since the length of the element formation region 21a is shorter, a length of the element formation region 21b in the Y direction is longer than the length of the element formation region 21b according to the first embodiment. Then, in the second embodiment, by increasing the length of the element formation region 21b, lengths in a gate length direction of the gate electrodes 32a₂ and 32a₃ of the amplification transistors AMP2 and AMP3 are respectively longer than the lengths in the gate length direction of the gate electrodes 32a₂ and 32a₃ of the amplification transistors AMP2 and AMP3 according to the first embodiment.

Although not illustrated in detail, in the second embodiment, each of the element formation regions 21a, 21b, and 21c is also defined by the element isolation region 25 including the conductive film 28 and the second insulating film 29, in a similar manner to the first embodiment. Then, each of the plurality of pixel transistors (the amplification transistors AMP1 to AMP3, the selection transistor SEL, and the reset transistor RST) included in the read circuit 17 is adjacent to the photoelectric converter 23 across the conductive film 28 of the element isolation region 25. Therefore, the solid-state imaging device 1B in which the amplification transistor AMP1 is disposed in the region including the virtual boundary line 16x₁ between the first pixel group 16A and the second pixel group 16B of the pixel block 15 as in the second embodiment can also produce effects similar to the effects produced by the solid-state imaging device 1A according to the first embodiment.

Note that it is a matter of course that a similar effect can be obtained in a case where another pixel transistor (the amplification transistors AMP 2 to 3, the selection transistor SEL, the reset transistor RST) is disposed in a region including the virtual boundary line 16x₁.

Furthermore, as in the second embodiment, by increasing a gate length (channel length) of each of the amplification transistors AMP2 and AMP3 as compared with the first embodiment, an area where the channel formation region and the photoelectric converter 23 are adjacent to each other across the element isolation region 25 in plan view, in other words, face each other increases. Therefore, the present technology is particularly effective in a case where the gate length is large as in the amplification transistors AMP2 and AMP3 according to the second embodiment.

### Third Embodiment

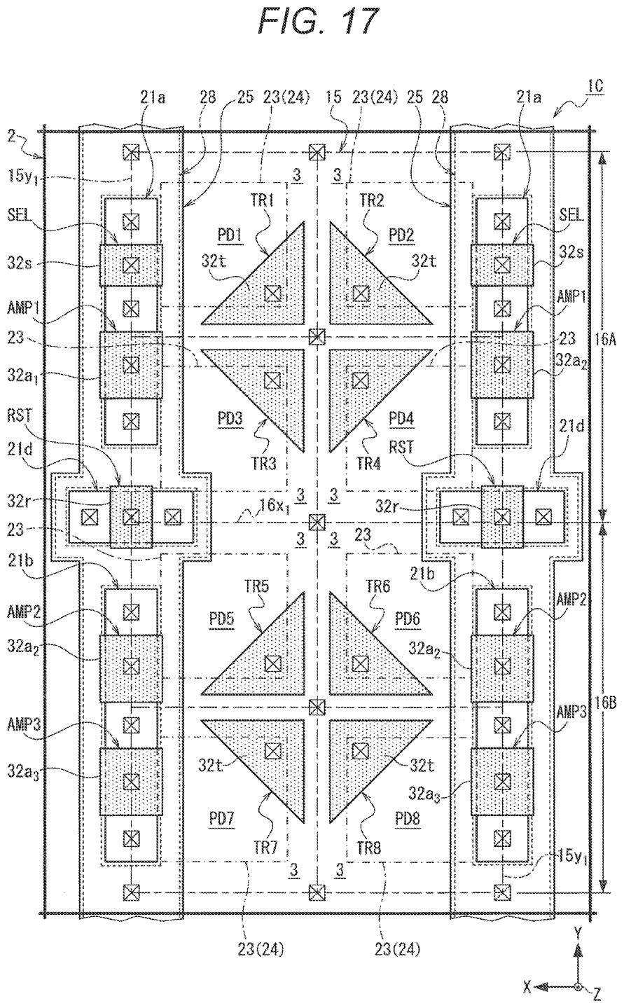

As illustrated in FIG. 17, a solid-state imaging device 1C according to a third embodiment of the present technology basically is basically similar in configuration to the solid-state imaging device 1A according to the first embodiment, and the orientation of the reset transistor RST is different among the pixel transistors included in the read circuit 17.

That is, as illustrated in FIG. 17, a solid-state imaging device 1C according to the third embodiment includes an island-shaped element formation region 21d disposed between the element formation region 21a and the element formation region 21b so as to be isolated from the element formation regions 21a and 21b.

As illustrated in FIG. 17, each of the element formation regions 21a and 21b extends along the Y direction, in a similar manner to the first embodiment. On the other hand, the element formation region 21d extends along the X direction. Although not illustrated in detail, the element formation region 21d is defined by the element isolation region 25 on the side of the first surface S1 of the semiconductor layer 21, in a similar manner to the element formation region 21b illustrated in FIGS. 9 and 10. Then, as illustrated in FIG. 17, the element formation region 21d is also surrounded by the conductive film 28 of the element isolation region 25 in a similar manner to the element formation regions 21a and 21b.

As illustrated in FIG. 17, in the element formation region 21b according to the third embodiment, only two amplification transistors AMP2 and AMP3 are provided side by side in the Y direction, unlike the first embodiment. Then, in the element formation region 21a according to the third embodiment, one amplification transistor AMP1 and one selection transistor SEL are provided side by side in the Y direction in a similar manner to the first embodiment.

As illustrated in FIG. 17, the reset transistor RST is provided in the element formation region 21d according to the third embodiment. Then, the reset transistor RST according to the third embodiment is provided in the element formation region 21d in an orientation in which, a pair of main electrode regions functioning as the source region and the drain region is aligned along the X direction on both sides of the channel formation region immediately below the gate electrode 32r.

Although not illustrated in detail, in the third embodiment, each of the element formation regions 21a, 21b, and 21d is also defined by the element isolation region 25 including the conductive film 28 and the second insulating film 29, in a similar manner to the first embodiment. Then, each of the plurality of pixel transistors (the amplification transistors AMP 1 to AMP3, the reset transistor RST, and the selection transistor SEL) included in the read circuit 17 is adjacent to the photoelectric converter 23 across the conductive film 28 of the element isolation region 25. Therefore, the solid-state imaging device 1C including the reset transistor RST provided in the element formation region 21d in an orientation in which the pair of main electrode regions functioning as the source region and the drain region is aligned along the X direction on both sides of the channel formation region immediately below the gate electrode 32r as in the third embodiment can also produce effects similar to the effects produced by the solid-state imaging device 1A according to the first embodiment.

Note that, in a case where another pixel transistor (the amplification transistors AMP2 to AMP3, the selection transistor SEL) is disposed in the element formation region 21d in an orientation changed as in the reset transistor RST illustrated in FIG. 17, it is a matter of course that a similar effect can be obtained by arranging the conductive film 28 in the element isolation region 25 between the pixel transistor and the photoelectric converter 23.

### Fourth Embodiment

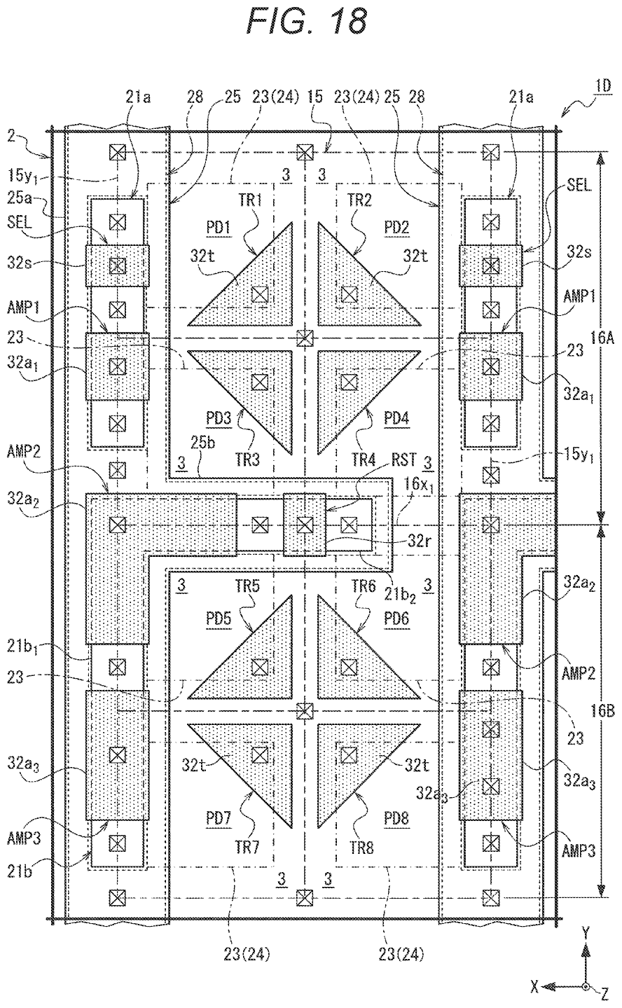

As illustrated in FIG. 18, a solid-state imaging device 1D according to a fourth embodiment is basically similar in configuration to the solid-state imaging device 1A according to the first embodiment, and the planar pattern of the element isolation region 25 and the planar pattern of the element formation region 21b are different.

That is, as illustrated in FIG. 18, in a similar manner to the second embodiment, the element isolation region 25 according to the fourth embodiment has a planar pattern including the first portion 25a disposed along the extending direction of the virtual boundary line 15y₁ (Y direction) in a region including the virtual boundary line 15y₁ between two pixel blocks 15 adjacent to each other in the X direction, and the second portion 25b disposed along the extending direction of the virtual boundary line 16x₁ (X direction) from the first portion 25a in a region including the virtual boundary line 16x₁ between the first pixel group 16A and the second pixel group 16B of the pixel block 15.

Then, as illustrated in FIG. 18, the element formation region 21b according to the fourth embodiment has a first portion 21b₁ disposed along an extending direction (Y direction) of the first portion 25a in the first portion 25a of the element isolation region 25, and a second portion 21b2 disposed along an extending direction of the second portion 25b from an end of the first portion 21b₁ in the second portion 25b of the element isolation region 25. That is, the planar pattern of the element formation region 21b according to the fourth embodiment has an L shape including a bent portion.

In the element formation region 21a, the amplification transistor AMP1 and the selection transistor SEL are provided side by side in the Y direction in a similar manner to the first embodiment. The reset transistor RST is provided in the second portion 21b₂ of the element formation region 21b. The amplification transistor AMP3 is provided in the first portion 21b₁ of the element formation region 21b. Then, the amplification transistor AMP2 is provided over the first portion 21b₁ and the second portion 21b₂ of the element formation region 21b.

In the amplification transistor AMP2 according to the fourth embodiment, as illustrated in FIG. 18, the gate electrode 32a₂ is provided over the first portion 21b₁ and the second portion 21b₂ of the element formation region 21b, and has an L-shaped planar shape. In a similar manner, the channel formation region immediately below the gate electrode 32a₂ is also provided over the first portion 21b₁ and the second portion 21b₂ of the element formation region 21b, and has an L-shaped planar shape reflecting the planar shape of the gate electrode 32a₂. Then, one of the pair of main electrode regions functioning as the source region and the drain region is provided in the first portion 21b₁ of the element formation region 21b, and the other is provided in the second portion 21b₂ of the element formation region 21b. That is, the amplification transistor AMP2 according to the fourth embodiment is provided at the bent portion of the element formation region 21b having an L-shaped plane.

Although not illustrated in detail, in the fourth embodiment, each of the element formation regions 21a and 21b is also defined by the element isolation region 25 including the conductive film 28 and the second insulating film 29, in a similar manner to the first embodiment. Then, each of the plurality of pixel transistors (the amplification transistors AMP1 to AMP3, the selection transistor SEL, and the reset transistor RST) included in the read circuit 17 is adjacent to the photoelectric converter 23 across the conductive film 28 of the element isolation region 25. Therefore, the solid-state imaging device 1D including the amplification transistor AMP2 disposed at the bent portion of the element formation region 21b having an L-shaped planar shape as in the fourth embodiment can also produce effects similar to the effects produced by the solid-state imaging device 1A according to the first embodiment.

Note that by arranging the amplification transistor AMP2 at the bent portion of the element formation region 21b, a degree of freedom of the layout of the pixel transistors included in the read circuit 17 is improved, which contributes to reduction in a planar size of the pixel block 15.

In addition, by arranging the amplification transistor AMP2 at the bent portion of the element formation region 21b, the gate length (channel length) of the amplification transistor AMP2 can be increased.

Furthermore, it is a matter of course that a similar effect can be obtained in a case where another pixel transistor is disposed at the bent portion of the element formation region 21b.

### Fifth Embodiment

A solid-state imaging device 1E according to a fifth embodiment of the present technology is basically similar in configuration to the solid-state imaging device 1A according to the first embodiment, but is different in the following configuration.

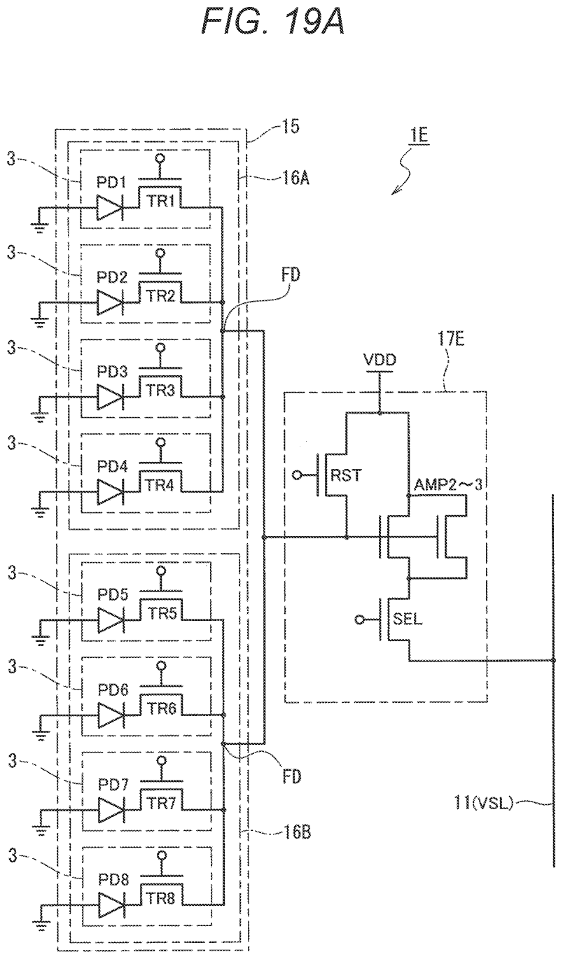

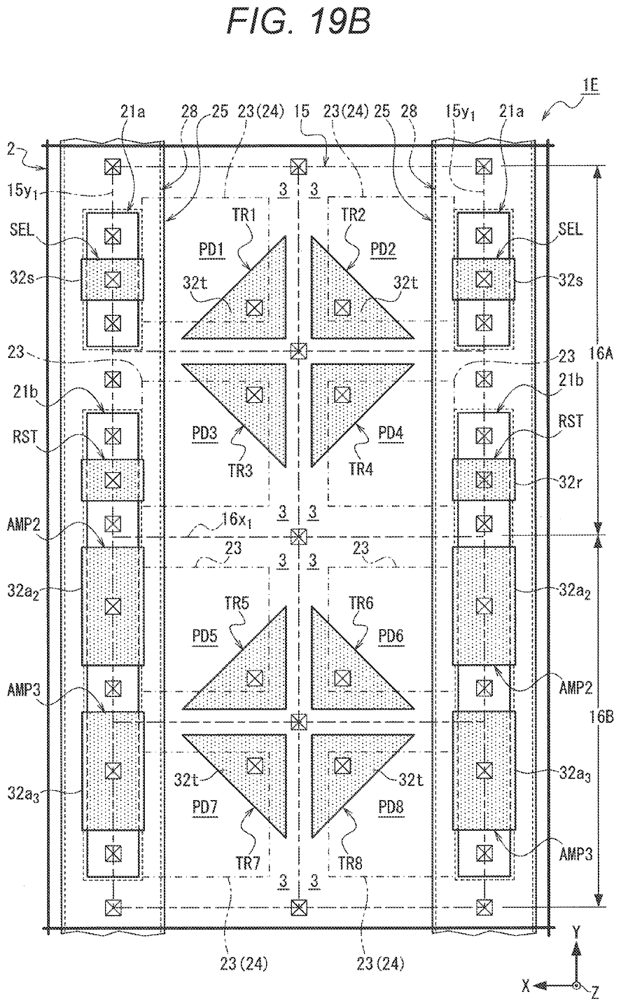

That is, the solid-state imaging device 1E according to the fifth embodiment of the present technology includes a read circuit 17E illustrated in FIG. 19A instead of the read circuit 17 illustrated in FIG. 3 according to the first embodiment.

As illustrated in FIG. 3, the read circuit 17 according to the first embodiment includes three amplification transistors AMP1 to AMP3, one selection transistor SEL, and one reset transistor RST as pixel transistors. However, as illustrated in FIG. 19A, the read circuit 17E according to the fifth embodiment includes two amplification transistors AMP2 and AMP3, one selection transistor SEL, and one reset transistor RST. Then, the layout of the pixel transistors (AMP2, AMP3, SEL, and RST) included in the read circuit 17E according to the fifth embodiment is as illustrated in FIG. 19B.

As illustrated in FIG. 19B, in a similar manner to the first embodiment, the element isolation region 25 according to the fifth embodiment is disposed along the extending direction of the virtual boundary line 15y₁ (Y direction) in a region including the virtual boundary line 15y₁ between two pixel blocks 15 adjacent to each other in the X direction. Then, the set of element formation regions 21a and 21b defined by the element isolation regions 25 is disposed for every pixel block 15. Each of the set of element formation regions 21a and 21b extends along the Y direction and is arranged in series at predetermined intervals. Each of the element isolation region 25 and the element formation regions 21a and 21b according to the fifth embodiment is also provided on the side of the first surface S1 of the semiconductor layer 21 in a similar manner to the first embodiment.

As illustrated in FIG. 19B, in the element formation region 21a according to the fifth embodiment, only one selection transistor SEL is provided, unlike the first embodiment. Then, in the element formation region 21b according to the fifth embodiment, two amplification transistors AMP2 and AMP3 and one reset transistor RST are provided side by side in the Y direction.

As illustrated in FIG. 19B, the gate lengths (channel lengths) of the two amplification transistors AMP2 and AMP3 according to the fifth embodiment are respectively larger than the gate lengths of the amplification transistors AMP2 and AMP3 according to the first embodiment. Therefore, the two amplification transistors AMP2 and AMP3 according to the fifth embodiment have a large area adjacent to the photoelectric converter 23 across the element isolation region 25.

However, since the two amplification transistors AMP2 and AMP3 according to the fifth embodiment are also adjacent to the photoelectric converter 23 across the conductive film 28 of the element isolation region 25, the fringe electric field from each of the gate electrodes 32a₂ and 32a₃ can be shielded by the conductive film 28 of the element isolation region 25 when each of the two amplification transistors AMP2 and AMP3 is driven. Then, the other pixel transistors (SEL and RST) are also adjacent to the photoelectric converter 23 across the conductive film 28 of the element isolation region 25. Therefore, the solid-state imaging device 1E according to the fifth embodiment can also produce effects similar to the effects produced by the solid-state imaging device 1A according to the first embodiment.

### Sixth Embodiment

A solid-state imaging device 1F according to a sixth embodiment of the present technology is basically similar in configuration to the solid-state imaging device 1A according to the first embodiment, but is different in the following configuration.

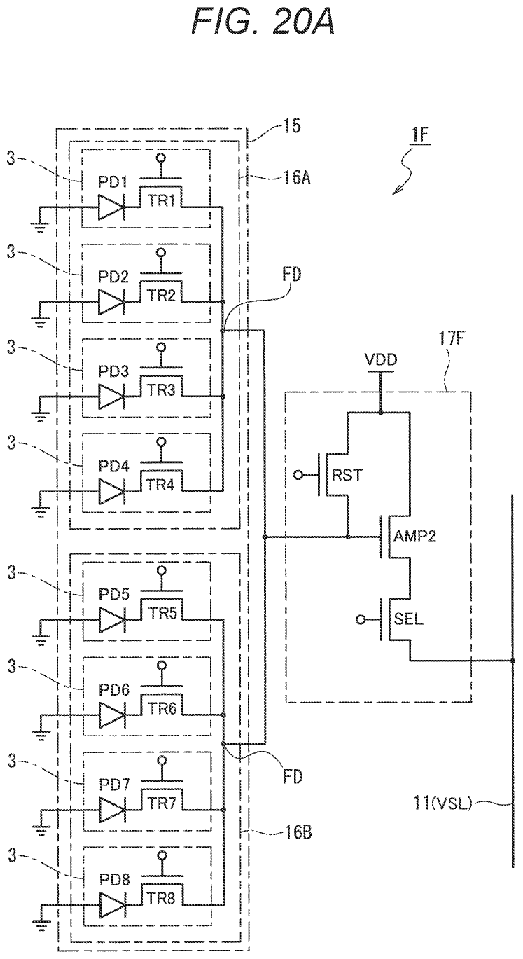

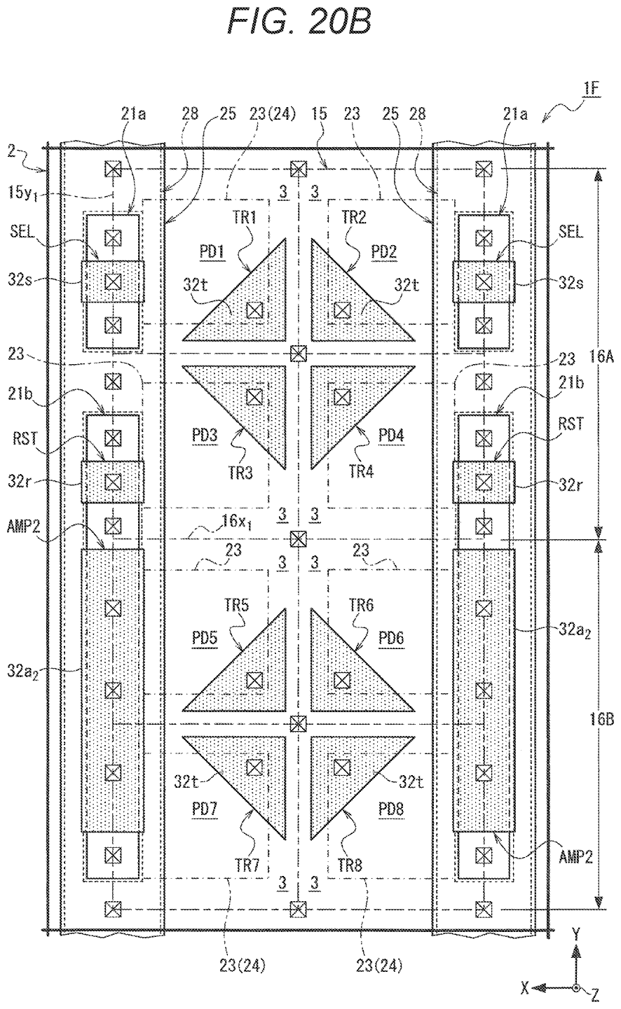

That is, the solid-state imaging device 1F according to the sixth embodiment of the present technology includes a read circuit 17F illustrated in FIG. 20A instead of the read circuit 17 illustrated in FIG. 3 according to the first embodiment.

As illustrated in FIG. 3, the read circuit 17 according to the first embodiment includes three amplification transistors AMP1 to AMP3, one selection transistor SEL, and one reset transistor RST as pixel transistors. However, as illustrated in FIG. 20A, the read circuit 17F according to the sixth embodiment includes one amplification transistors AMP2, one selection transistor SEL, and one reset transistor RST. The layout of the pixel transistors included in the read circuit 17F according to the sixth embodiment is as illustrated in FIG. 20B.

As illustrated in FIG. 20B, in the element formation region 21a according to the sixth embodiment, one selection transistor SEL is provided. Then, in the element formation region 21b, one amplification transistor AMP2 and one reset transistor RST are provided side by side in the Y direction.

As illustrated in FIG. 20B, the gate length (channel length) of the amplification transistor AMP2 according to the sixth embodiment is larger than the gate length of the amplification transistor AMP2 according to the first embodiment. Therefore, the amplification transistor AMP2 according to the sixth embodiment has a larger area adjacent to the photoelectric converter 23 across the element isolation region 25 than the amplification transistor AMP2 according to the first embodiment.

However, since the amplification transistor AMP2 according to the sixth embodiment is also adjacent to the photoelectric converter 23 across the conductive film 28 of the element isolation region 25, the fringe electric field from the gate electrode 23a₂ can be shielded by the conductive film 28 of the element isolation region 25 when the amplification transistor AMP2 is driven. Then, the other pixel transistors (the selection transistor SEL and the reset transistor RST) are also adjacent to the photoelectric converter 23 across the conductive film 28 of the element isolation region 25. Therefore, the solid-state imaging device 1F according to the fifth embodiment can also produce effects similar to the effects produced by the solid-state imaging device 1A according to the first embodiment.

### Seventh Embodiment

A solid-state imaging device 1G according to a seventh embodiment of the present technology is basically similar in configuration to the solid-state imaging device 1A according to the first embodiment, but is different in the following configuration.

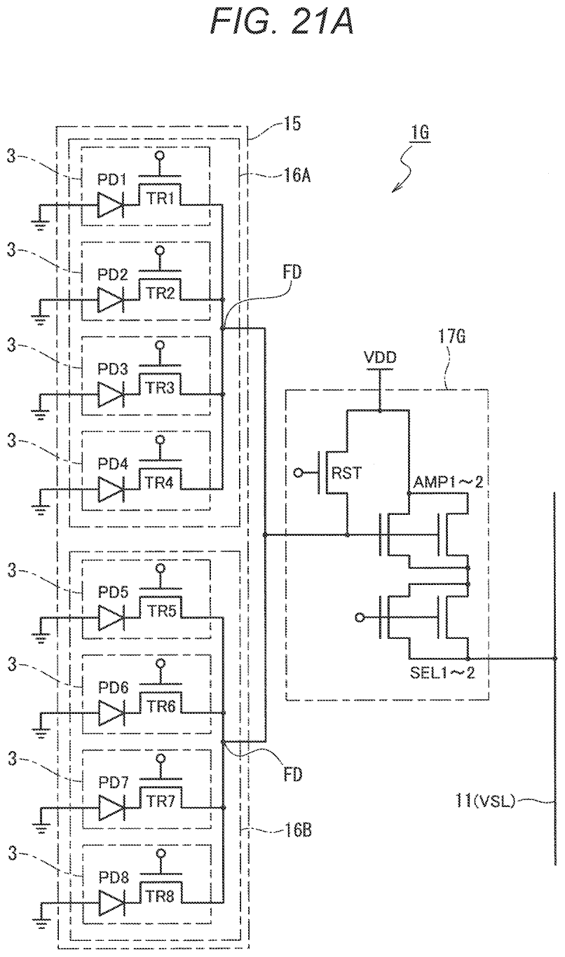

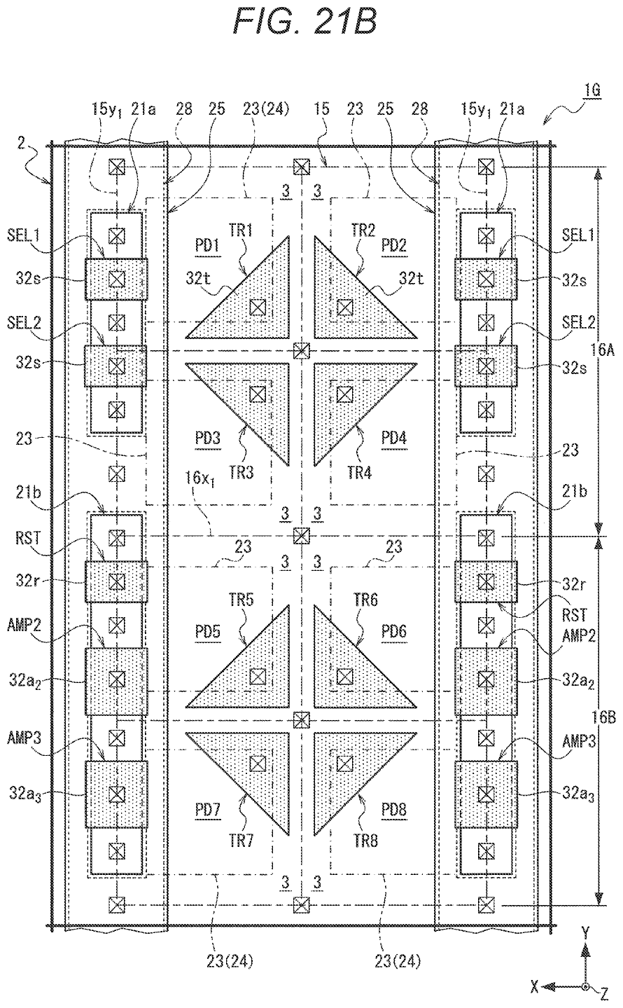

That is, the solid-state imaging device 1G according to the seventh embodiment of the present technology includes a read circuit 17G illustrated in FIG. 21A instead of the read circuit 17 illustrated in FIG. 3 according to the first embodiment.

As illustrated in FIG. 3, the read circuit 17 according to the first embodiment includes three amplification transistors AMP1 to AMP3, one selection transistor SEL, and one reset transistor RST as pixel transistors. However, as illustrated in FIG. 21A, the read circuit 17E according to the seventh embodiment includes two amplification transistors AMP2 and AMP3, two selection transistors SEL1 and SEL2, and one reset transistor RST as pixel transistors. The two amplification transistors AMP2 and AMP3 are connected in parallel. The two selection transistors SEL1 and SEL2 are also connected in parallel. Then, the layout of the pixel transistors (AMP2, AMP3, SEL1, SEL2, and RST) included in the read circuit 15G according to the seventh embodiment is as illustrated in FIG. 21B.

As illustrated in FIG. 21B, in a similar manner to the first embodiment, the element isolation region 25 according to the seventh embodiment is disposed along the extending direction of the virtual boundary line 15y₁ (Y direction) in a region including the virtual boundary line 15y₁ between two pixel blocks 15 adjacent to each other in the X direction. Then, the set of element formation regions 21a and 21b defined by the element isolation regions 25 is disposed for every pixel block 15. Each of the set of element formation regions 21a and 21b extends along the Y direction and is arranged in series at predetermined intervals. Each of the element isolation region 25 and the element formation regions 21a and 21b according to the seventh embodiment is also provided on the side of the first surface S1 of the semiconductor layer 21 in a similar manner to the first embodiment.

As illustrated in FIG. 21B, in the element formation region 21a according to the seventh embodiment, the two selection transistors SEL1 and SEL2 are provided, unlike the first embodiment. Then, in the element formation region 21b according to the seventh embodiment, two amplification transistors AMP2 and AMP3 and one reset transistor RST are provided side by side in the Y direction in a similar manner to the first embodiment.

Although not illustrated in detail, in the seventh embodiment, each of the element formation regions 21a and 21b is also defined by the element isolation region 25 including the conductive film 28 and the second insulating film 29, in a similar manner to the first embodiment. Then, each of the plurality of pixel transistors (the amplification transistors AMP2 and AMP3, the selection transistors SEL1 and SEL2, and the reset transistor RST) included in the read circuit 17G is adjacent to the photoelectric converter 23 across the conductive film 28 of the element isolation region 25. Therefore, the solid-state imaging device 1G including the read circuit 17G including the two amplification transistors AMP1 and AMP2, the two selection transistors SEL1 and SEL2, and the one reset transistor RST as in the seventh embodiment can also produce effects similar to the effects produced by the solid-state imaging device 1A according to the first embodiment.

### Eighth Embodiment

A solid-state imaging device 1H according to an eighth embodiment of the present technology is basically similar in configuration to the solid-state imaging device 1A according to the first embodiment, but is different in the following configuration.

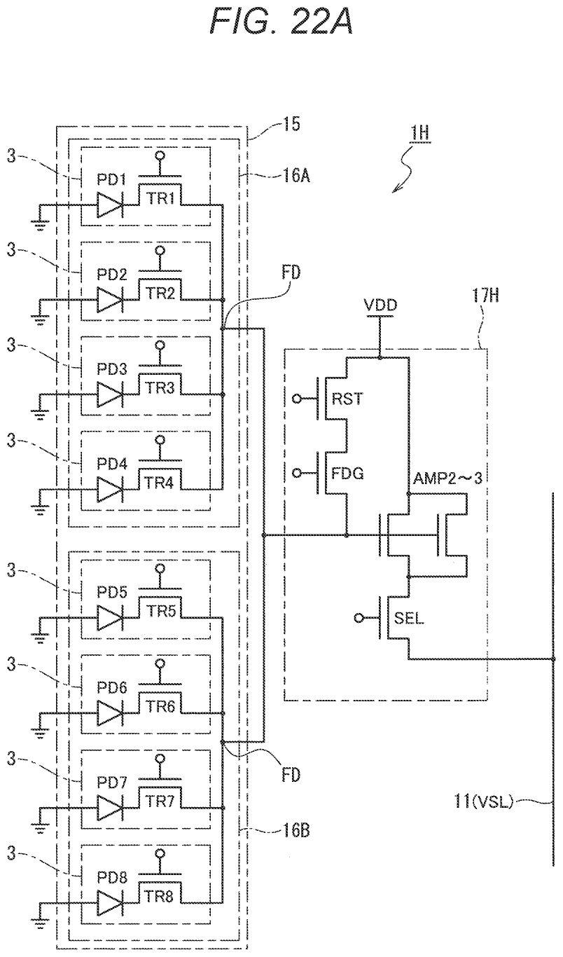

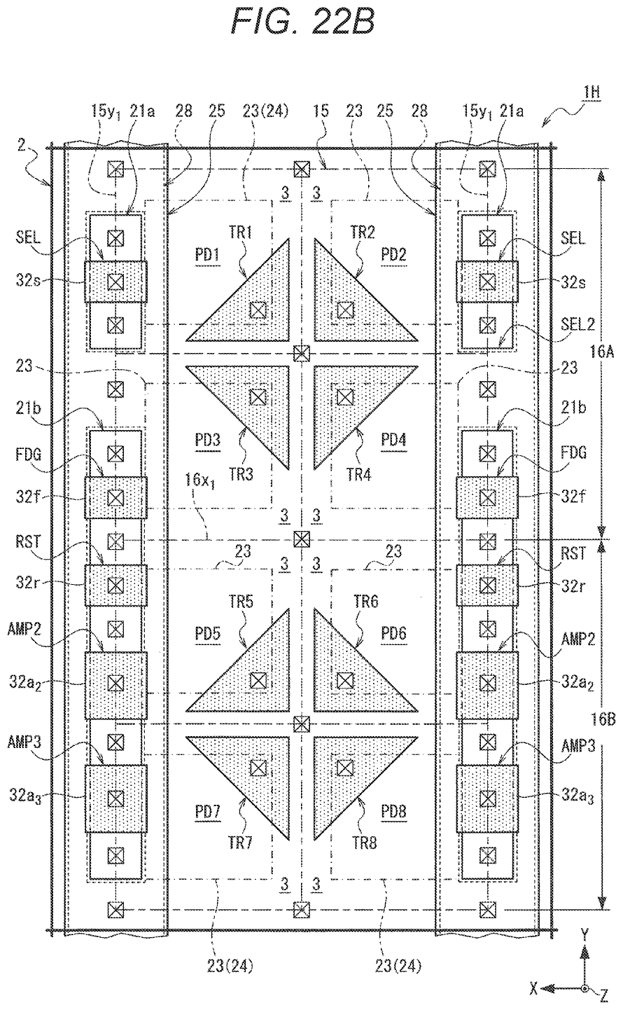

That is, the solid-state imaging device 1H according to the eighth embodiment of the present technology includes a read circuit 17H illustrated in FIG. 22A instead of the read circuit 17 illustrated in FIG. 4 according to the first embodiment. The read circuit 17H includes two amplification transistors AMP2 and AMP3, one selection transistor SEL, one reset transistor RST, and one switching transistor FDG.

As illustrated in FIG. 22A, the switching transistor FDG according to the eighth embodiment has a source region (input end of the read circuit 17H) electrically connected to the charge holding region FD, and has a drain region electrically connected to a source region of the reset transistor RST and the gate electrode of each of the two amplification transistors AMP2 and AMP3. Then, the switching transistor FDG has a gate electrode electrically connected to a switching transistor drive line among the pixel drive lines 10 as described with reference to FIG. 2. The switching transistor FDG controls charge accumulation of the charge holding region FD, and adjusts a multiplication factor of the voltage according to the potential multiplied by the amplification transistors AMP.

As illustrated in FIG. 22A, the reset transistor RST according to the eighth embodiment has the source region electrically connected to the drain region of the switching transistor FDG, and has the drain region electrically connected to the power supply line VDD. Then, the gate electrode of the reset transistor RST is electrically connected to the reset transistor drive line among the pixel drive lines 10 as described with reference to FIG. 2.

As illustrated in FIG. 22A, each of the two amplification transistors AMP2 and AMP3 according to the eighth embodiment has the source region electrically connected to the drain region of the selection transistor SEL, and has the drain region electrically connected to the power supply line VDD. Then, each of the two amplification transistors AMP2 and AMP3 has the gate electrode electrically connected to the source region of the switching transistor FDG and the charge holding region FD. That is, the two amplification transistors AMP are connected in parallel.

As illustrated in FIG. 22A, the selection transistor SEL has a source region according to the eighth embodiment has the source region electrically connected to the vertical signal line 11, and has the drain region electrically connected to the source region of each of the two amplification transistors AMP2 and AMP3. Then, the gate electrode of the selection transistor SEL is electrically connected to the selection transistor drive line among the pixel drive lines 10 as described with reference to FIG. 2.

The layout of the pixel transistors (AMP2, AMP3, SEL, RST, and FDG) included in the read circuit 15H according to the eighth embodiment is as illustrated in FIG. 22B.

As illustrated in FIG. 22B, in a similar manner to the first embodiment, the element isolation region 25 according to the eighth embodiment is disposed along the extending direction of the virtual boundary line 15y₁ (Y direction) in a region including the virtual boundary line 15y₁ between two pixel blocks 15 adjacent to each other in the X direction. Then, the set of element formation regions 21a and 21b defined by the element isolation regions 25 is disposed for every pixel block 15. Each of the set of element formation regions 21a and 21b extends along the Y direction and is arranged in series at predetermined intervals. Although not illustrated in detail, each of the element isolation region 25 and the element formation regions 21a and 21b according to the eighth embodiment is also provided on the side of the first surface S1 of the semiconductor layer 21 in a similar manner to the first embodiment.

As illustrated in FIG. 22B, the element formation region 21a according to the eighth embodiment has a shorter length in the Y direction than the element formation region 21a according to the first embodiment. On the other hand, the element formation region 21b according to the eighth embodiment has a longer length in the Y direction than the element formation region 21b according to the first embodiment.

As illustrated in FIG. 22B, in the element formation region 21a according to the eighth embodiment, only one selection transistor SEL is provided, unlike the first embodiment. Then, in the element formation region 21b according to the eighth embodiment, two amplification transistors AMP2 and AMP3, one reset transistor RST, and one switching transistor FDG are provided side by side in the Y direction, unlike the first embodiment. In a similar manner to the other pixel transistors (the amplification transistors AMP1 and AMP2, the selection transistor SEL, and the reset transistor RST), the switching transistor FDG includes, for example, a MOSFET as a field effect transistor.

Although not illustrated in detail, in the eighth embodiment, each of the element formation regions 21a and 21b is also defined by the element isolation region 25 including the conductive film 28 and the second insulating film 29, in a similar manner to the first embodiment. Then, each of the plurality of pixel transistors (the amplification transistors AMP2 and AMP3, the selection transistor SEL, the reset transistor RST, and the switching transistor FDG) included in the read circuit 17H is adjacent to the photoelectric converter 23 across the conductive film 28 of the element isolation region 25. Therefore, the solid-state imaging device 1H including the read circuit 17H including the two amplification transistors AMP1 and AMP2, the one selection transistor SEL, the one reset transistor RST, and the one switching transistor FDG as pixel transistors as in the eighth embodiment can also produce effects similar to the effects produced by the solid-state imaging device 1A according to the first embodiment.

### Ninth Embodiment

A solid-state imaging device 1I according to a ninth embodiment of the present technology is basically similar in configuration to the solid-state imaging device 1A according to the first embodiment 1, but is different in the configuration of the element isolation region.

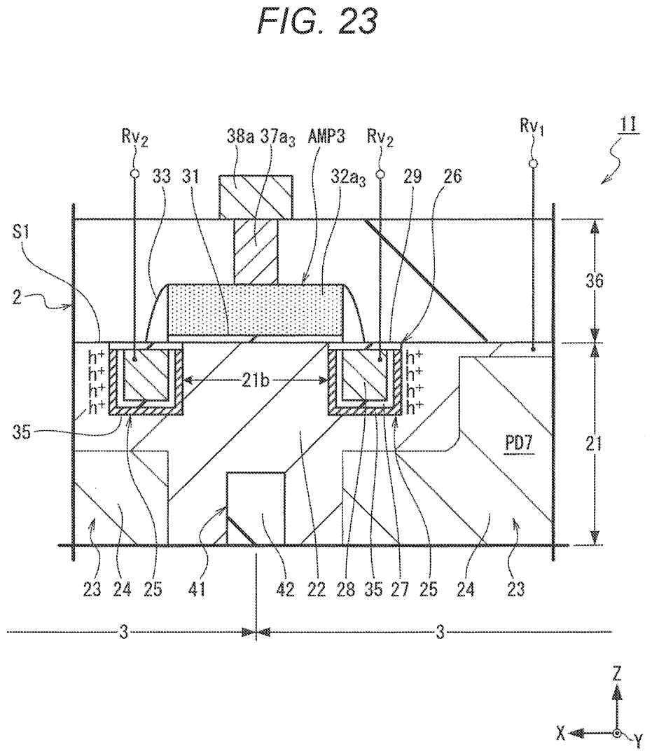

That is, as illustrated in FIG. 23, the element isolation region 25 according to the ninth embodiment further includes a pinning film 35 interposed between the groove 26 and the first insulating film 27. The pinning film 35 is provided along a wall surface and a bottom surface in the groove 26 of the semiconductor layer 21 and controls generation of dark current. As the pinning film 35, for example, hafnium oxide (HfO₂), tantalum oxide (Ta₂O₅), or the like can be used.

The solid-state imaging device 1I according to the ninth embodiment can produce effects similar to the effects produced by the solid-state imaging device 1A according to the first embodiment, and secure pinning of a side wall of the element isolation region 25 by the pinning film 35.

### Tenth Embodiment

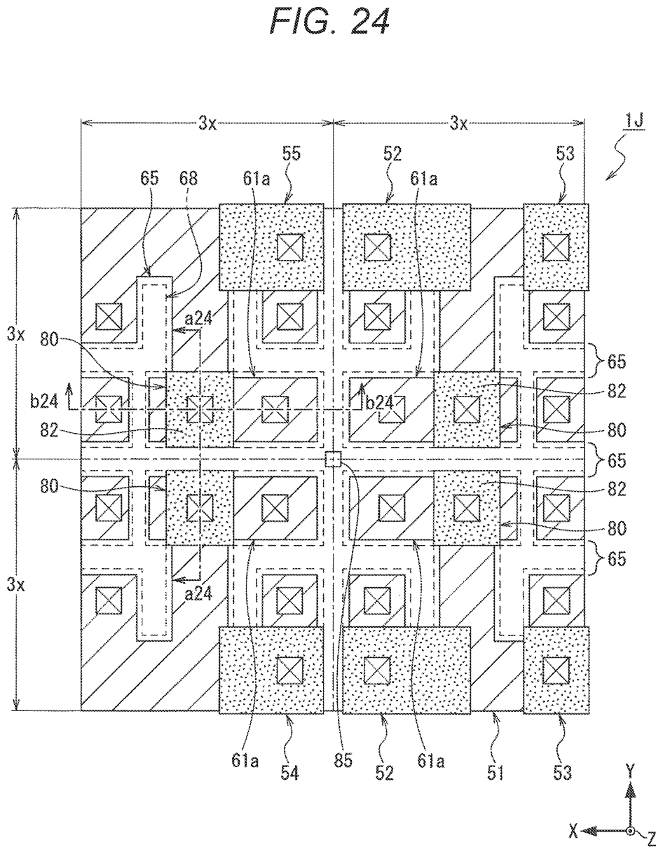

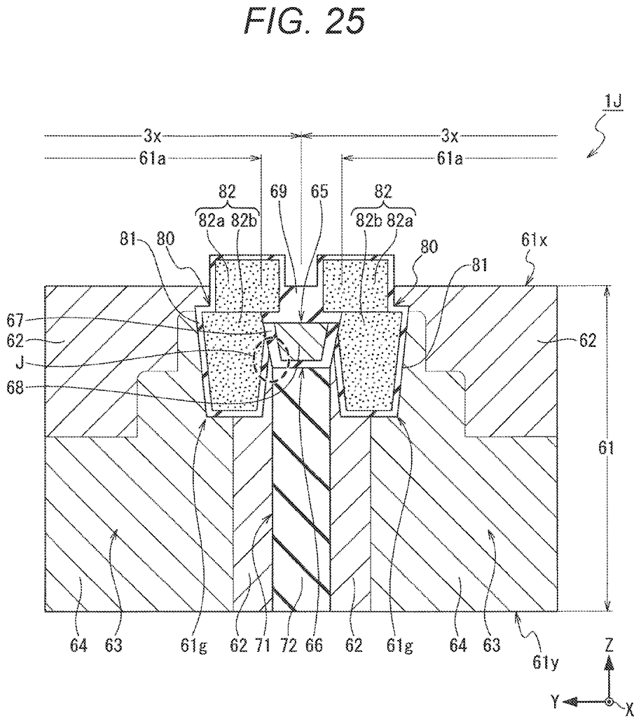

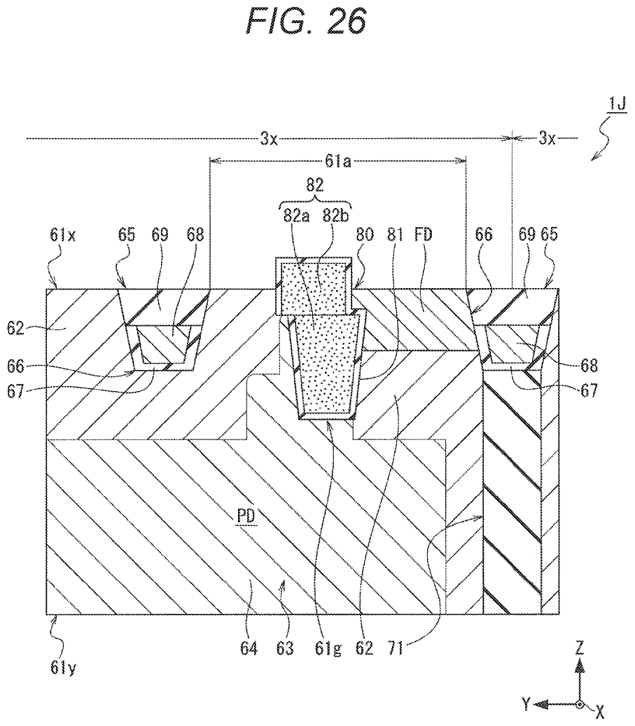

A solid-state imaging device 1J according to a tenth embodiment of the present technology includes a pixel block 51 illustrated in FIG. 24 and a semiconductor layer 61 illustrated in FIGS. 25 and 26. The pixel block 51 is configured in the semiconductor layer 61.

As illustrated in FIG. 24, the pixel block 51 includes four pixels 3x arranged in a 2×2 array in each of the X direction and the Y direction as one unit. In addition, the pixel block 51 further includes, for example, two amplification transistors 52, two selection transistors 53, one reset transistor 54, and one switching transistor (dummy transistor) 55 as the pixel transistors included in a read circuit shared by the four pixels 3x. Furthermore, the pixel block 51 further includes a transfer transistor 80 provided for every pixel 3x. Then, as illustrated in FIGS. 25 and 26, the pixel block 51 further includes a p-type (second conductivity type) semiconductor region 62, a photoelectric converter 63, and a charge holding region FD provided in the semiconductor layer 61. Each of the amplification transistor 52, the selection transistor 53, the reset transistor 54, the switching transistor 55, and the transfer transistor 80 includes, for example, a MOSFET as a field effect transistor.

As illustrated in FIGS. 25 and 26, the semiconductor layer 61 has a first surface 61x and a second surface 62y located opposite to each other. In the tenth embodiment, the first surface 61x of the semiconductor layer 61 may be also referred to as an element formation surface or main surface, and the second surface S61y of the semiconductor layer 61 may be referred to as a light incident surface or back surface. Then, in the solid-state imaging device 1J according to the tenth embodiment, light incident from the second surface (light incidence surface, back surface) 61x of the semiconductor layer 61 is also photoelectrically converted by a photoelectric converter 63 (photoelectric conversion element PD) provided in the semiconductor layer 61.

As illustrated in FIGS. 25 and 26, the semiconductor layer 61 includes an element isolation region 65 and a plurality of island-shaped element formation regions including an island-shaped element formation region 61a defined by the element isolation region 65 on the side of the first surface 61x. In addition, the semiconductor layer 61 further includes a pixel isolation region 71 on the side of the second surface 61y. Furthermore, the semiconductor layer 61 further includes the p-type semiconductor region 62 and the photoelectric converter 63 described above. The photoelectric converter 63 is surrounded by the p-type semiconductor region 62. The semiconductor layer 61 includes, for example, a p-type single crystal silicon substrate.

Note that, although not illustrated, a planarization film, a color filter, a microlens, and the like are provided on the side of the second surface 61y of the semiconductor layer 61 in a similar manner to the above-described embodiments.

As illustrated in FIGS. 24A, 25, and 26, the pixel isolation region 71 extends from the second surface 61y toward the first surface S1 of the semiconductor layer 21, and electrically and optically isolates the pixels 3x adjacent to each other in the two-dimensional plane. The pixel isolation region 71 has, but not limited to, for example, a trench structure in which an insulating film 72 is embedded in a groove extending from the second surface 61y of the semiconductor layer 61 toward the first surface 61x and is separated from the first surface 61x of the semiconductor layer 61. The pixel isolation region 71 isolates the side of the second surface 61y of the semiconductor layer 61 for every pixel 3x. The pixel isolation region 71 of the tenth embodiment has, but not limited to, a depth in contact with the element isolation region 65 provided on the side of the first surface 61x of the semiconductor layer 61, for example.

As illustrated in FIGS. 25 and 26, the photoelectric converter 63 is provided for every pixel 3x. The photoelectric converter 23 includes a n-type (first conductivity type) semiconductor region 24. Then, the photoelectric converter 23 constitutes the photoelectric conversion element PD.

As illustrated in FIGS. 25 and 26, the p-type semiconductor region 62 is provided for every pixel 3x between the photoelectric converter 63 and the first surface 61x of the semiconductor layer 61 and between the photoelectric converter 63 and the pixel isolation region 71. The p-type semiconductor region 62 located between the photoelectric converter 63 and the pixel isolation region 71 is provided from the first surface 61x toward the second surface 61y of the semiconductor layer 61. The pixel isolation region 71 is included in the p-type semiconductor region 62 and is separated from the photoelectric converter 63 with the p-type semiconductor region 62 interposed therebetween. The p-type semiconductor region 62 includes one semiconductor region or a plurality of semiconductor regions. The p-type semiconductor region 62 and the n-type semiconductor region 64 of the photoelectric converter 63 form a pn junction for every pixel 3x.

As illustrated in FIG. 24, the element formation region 61a defined by the element isolation region 65 is provided for every pixel 3x. That is, four element formation regions 61a are provided in the pixel block 51. In each of the four element formation regions 61a, the transfer transistor 80 described above is provided for every pixel 3x. The four element formation regions 61a are adjacent to each other in each of the X direction and the Y direction across the element isolation region 65. Then, each of the four element formation regions 61a is surrounded by the element isolation region 65.

As illustrated in FIG. 24, the transfer transistor 80 described above is provided in each of the four element formation regions 61a. In addition, as illustrated in FIGS. 25 and 26, the p-type semiconductor region 62, the photoelectric converter 23, and the charge holding region FD are provided in each of the four element formation regions 61a. The charge holding region FD includes an n-type semiconductor region.

As illustrated in FIGS. 25 and 26, the transfer transistor 80 includes a gate groove 61g provided on the side of the first surface of the semiconductor layer 61, a gate insulating film 81 provided along a wall surface and a bottom surface in the gate groove 61g, and a gate electrode 82 provided in the gate groove 61g with the gate insulating film 81 interposed therebetween. Furthermore, the transfer transistor 80 includes a channel formation region including the p-type semiconductor region 62 arranged on a side wall of the gate electrode 82 with the gate insulating film 81 interposed therebetween, the photoelectric converter 23 functioning as the source region, and the charge holding region FD functioning as the drain region.

The charge holding region FD is provided on the side of the first surface 61x of the semiconductor layer 61 and overlaps the photoelectric converter 63 with the p-type semiconductor region 62 interposed therebetween.

The gate electrode 82 includes a first portion (vertical gate electrode portion) 82a provided in the gate groove 61g with the gate insulating film 81 interposed therebetween, and a second portion (transfer gate electrode portion) 82b provided in the gate groove 61g with the gate insulating film 81 interposed therebetween and closer to the first surface of the semiconductor layer 61 than the first portion 82a and electrically connected to the first portion 82a. The gate electrode 82 includes, for example, a polycrystalline silicon film doped with an impurity to make the resistance value lower. The gate insulating film 81 includes, for example, a silicon oxide film.

As illustrated in FIGS. 25 and 26, the first portion 82a and the second portion 82b of the gate electrode 82 are disposed along a depth direction of the semiconductor layer 61 (Z direction). The photoelectric converter 63 functioning as the drain region and the charge holding region functioning as the source region are disposed along the depth direction of the semiconductor layer 61 with the p-type semiconductor region 62 of the channel formation region interposed therebetween. That is, unlike the transfer transistor TR according to the first embodiment described above, the transfer transistor 80 according to the tenth embodiment has a vertical structure in which the source region and the drain region are disposed in the depth direction of the semiconductor layer 61.

As illustrated in FIGS. 25 and 26, the element isolation region 65 includes a groove 66 provided on the side of the first surface 61x of the semiconductor layer 61, a conductive film 68 provided in the groove 66 with the first insulating film 67 interposed therebetween, and a second insulating film 69 provided on the side of the first surface 61x of the semiconductor layer 61 so as to overlap the conductive film 68 in plan view. The element isolation region 65 is provided in the surface layer of the first surface 61x of the semiconductor layer 61. Then, the element isolation region 65 has a thickness in a thickness direction of the semiconductor layer 61 (Z direction) and is separated from the second surface 61y. That is, the element isolation region 65 has a shallow trench isolation (STI) structure.

The first insulating film 67 is provided along a wall surface and a bottom surface in the groove 66, and is interposed between the semiconductor layer 61 and the conductive film 68. The second insulating film 29 covers the conductive film 28. In other words, an upper surface of the conductive film 68 located on the side of the first surface 61x of the semiconductor layer 61 is covered with the second insulating film 69. The first insulating film 67 and the second insulating film 69 each include, for example, a silicon oxide film. The second insulating film 29 has, but not limited to, a larger film thickness than the gate insulating film 81 of the transfer transistor 80, for example.

As illustrated in FIG. 24, the conductive film 68 is provided, but not limited to, in the entire region of the element isolation region 65 in plan view. Then, each of the four element formation regions 61a is surrounded by the conductive film 68.

In addition, a contact portion 85 for applying a reference potential to the conductive film 68 of the element isolation region 65 is provided in the element isolation region 65 in a central portion surrounded by the four pixels 3x.

Note that the two pixel transistors 52, the two selection transistors 53, the one reset transistor 54, and the one switching transistor 55 are provided in another element formation region defined by the element isolation region 65. Then, the another element formation region is also surrounded by the conductive film 68.

A first reference potential is applied to the p-type semiconductor region 62 as a power supply potential. Then, a second reference potential is applied to the conductive film 68 of the element isolation region 65 as a power supply potential. In the tenth embodiment, although not limited thereto, for example, 0 V is applied to the p-type semiconductor region 62 as the first reference potential, and for example, 1.2 V is applied to the conductive film 68 of the element isolation region 65 as the second reference potential. The application of the first reference potential to the conductive film 68 is held during driving of the transfer transistor 80.

As illustrated in FIGS. 24 and 25, the element isolation region 65 between two element formation regions 61a adjacent to each other in the Y direction among the four element formation regions 61a of the pixel block 51 is disposed at a position overlapping the pixel isolation region 71 in plan view and is in contact with the pixel isolation region 71. Furthermore, as illustrated in FIGS. 24 and 26, the element isolation region 65 between two element formation regions 61a adjacent to each other in the X direction among the four element formation regions 61a of the pixel block 51 is disposed at a position overlapping the pixel isolation region 71 in plan view and is in contact with the pixel isolation region 71.

As illustrated in FIGS. 24 and 25, the transfer transistors 80 of the two pixels 3x adjacent to each other in the Y direction among the four pixels 3x of the pixel block 51 have the respective gate electrodes 82 adjacent to each other across the element isolation regions 65, the element isolation region 65 including the conductive film 68 and the second insulating film 69. Then, for example, −1.2 V is applied to the gate electrode 82 of one transfer transistor 80 as a gate potential, and for example, 2.8 V is applied to the gate electrode 82 of the other transfer transistor 80 as a gate potential.

As described above, since the element isolation region 65 including the conductive film 68 is provided between the gate electrodes 82 of the two transfer transistors 80 to which different gate potentials are applied, the fringe electric field from the gate electrode 82 can be shielded by the conductive film 68 of the element isolation region 65 during driving of the two transfer transistors 80. Accordingly, pinning at an end of the element isolation region 65 (a region J surrounded by a broken line in FIG. 25) on the side of the gate electrode 82 can be secured. Therefore, the solid-state imaging device 1J according to the tenth embodiment can suppress deterioration of white spot and dark current characteristics in a similar manner to the solid-state imaging device 1A according to the first embodiment.

In addition, the element isolation region 65 according to the tenth embodiment further includes the second insulating film 69 overlapping the conductive film 68 in plan view on the side of the first surface 61x of the semiconductor layer 61. Accordingly, electrical conduction between the gate electrode 82 of the transfer transistor 80 and the conductive film 68 of the element isolation region 65 can be prevented. Therefore, the solid-state imaging device 1J according to the tenth embodiment can suppress the deterioration of white spot and dark current characteristics, and can prevent the electrical conduction between the gate electrode 82 of the transfer transistor 80 and the conductive film 68 of the element isolation region 65.

<<Modifications>>

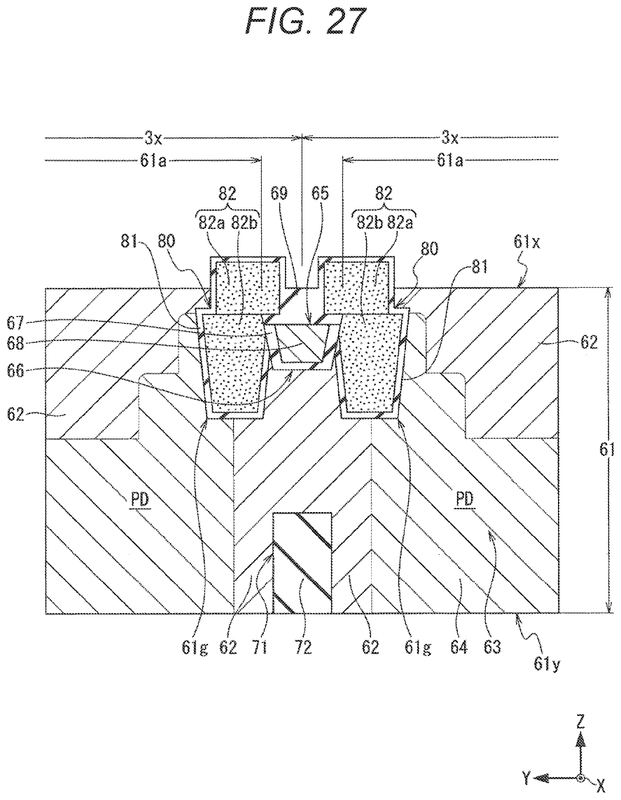

In the tenth embodiment, a case has been described where the pixel isolation region 71 has a depth in contact with the element isolation region 65. However, the present technology is not limited to the tenth embodiment. For example, as illustrated in FIG. 27, the present technology can also be applied to a case where the pixel isolation region 71 has a depth so as to be separated from the element isolation region 65.

### Eleventh Embodiment

<<Examples of Application to Electronic Apparatus>>>

The present technology (technology of the present disclosure) can be applied to various electronic apparatuses such as an imaging device such as a digital still camera or a digital video camera, a mobile phone having an imaging function, or other devices having an imaging function, for example.

FIG. 28 is a diagram illustrating a schematic configuration of an electronic apparatus (for example, a camera) according to an eleventh embodiment of the present technology.

As illustrated in FIG. 28, an electronic apparatus 100 includes the solid-state imaging device 101, the optical lens 102, a shutter device 103, a drive circuit 104, and a signal processing circuit 105. The electronic apparatus 100 indicates an embodiment in a case where the solid-state imaging devices 1A, 1B, 1C, 1D, 1E, 1F, 1G, 1H, 1H, and 1J according to the first to tenth embodiments of the present technology are each used as the solid-state imaging device 101 in an electronic device (for example, a camera).

The optical lens 102 forms an image of image light (incident light 106) from a subject on the imaging surface of the solid-state imaging device 101. As a result, signal charges are accumulated in the solid-state imaging device 101 over a certain period. The shutter device 103 controls a light irradiation period and a light shielding period for the solid-state imaging device 101. The drive circuit 104 supplies a drive signal for controlling a transfer operation of the solid-state imaging device 101 and a shutter operation of the shutter device 103. A signal of the solid-state imaging device 101 is transferred by the drive signal (timing signal) supplied from the drive circuit 104. The signal processing circuit 105 performs various types of signal processing on a signal (pixel signal) output from the solid-state imaging device 101. A video signal subjected to the signal processing is stored in a storage medium such as a memory or output to a monitor.

With such a configuration, the electronic apparatus 100 according to the eleventh embodiment causes a light anti-reflector in the solid-state imaging device 101 to inhibit light reflection of the light shielding film and the insulating film in contact with an air layer, and thus, it is possible to inhibit deviation and improve image quality.

Note that the electronic apparatus 100 to which the solid-state imaging devices 1A to 1J can be applied is not limited to a camera, and the solid-state imaging devices 1A to 1J can be also applied to other electronic apparatuses. For example, the solid-state imaging devices 1A to 1J may be applied to an imaging device such as a camera module for a mobile device such as a mobile phone or a tablet terminal.

Furthermore, the present technology can be applied to any photodetector including not only the above-described solid-state imaging device as the image sensor but also a ranging sensor that is also called a time of flight (ToF) sensor and measures a distance, and the like. The ranging sensor is a sensor that emits irradiation light toward an object, detects reflected light that is the irradiation light reflected from a surface of the object, and calculates a distance to the object on the basis of a flight time from the emission of the irradiation light to reception of the reflected light. As a structure of an element isolation region of the ranging sensor, the structure of the element isolation region described above may be employed.

Note that the present technology may also have the following configurations.

(1)

A photodetector including
a semiconductor layer that has a first surface and a second surface located opposite to each other and is provided with an element isolation region on a side of the first surface,
a photoelectric converter provided in the semiconductor layer, and
a transistor provided adjacent to the photoelectric converter on the side of the first surface of the semiconductor layer across the element isolation region, in which
the element isolation region includes a conductive film provided in a groove on the side of the first surface of the semiconductor layer with a first insulating film interposed therebetween, and a second insulating film provided on the side of the first surface of the semiconductor layer so as to overlap the conductive film.

(2)

The photodetector according to (1) described above, in which the second insulating film covers the conductive film.

(3)

The photodetector according to (1) or (2) described above, in which the conductive film is electrically connected to a wire to which a potential is applied.

(4)

The photodetector according to any of (1) to (3) described above, in which
the photoelectric converter includes a first semiconductor region of a first conductivity type, and
a second semiconductor region of a second conductivity type is provided in the semiconductor layer between the element isolation region and the first semiconductor region.

(5)

The photodetector according to any of (1) to (4) described above, in which the conductive film includes a conductive material having a deeper Fermi level than the second semiconductor region.

(6)

The photodetector according to any of (1) to (4) described above, in which the conductive film includes a conductive material having a deeper work function than the second semiconductor region.

(7)

The photodetector according to any of (1) to (4) described above, in which
a reference potential is applied to the second semiconductor region, and
a negative potential lower than the reference potential is applied to the conductive film.

(8)

The photodetector according to any of (1) to (7) described above, in which
the semiconductor layer includes an element formation region defined by the element isolation region on the side of the first surface,
the transistor includes a gate electrode provided over the element formation region and the element isolation region, and
the second insulating film is interposed between the conductive film and the gate electrode.

(9)

The photodetector according to any of (1) to (7) described above, in which
the transistor includes a gate insulating film provided in the element formation region, and
the second insulating film is provided in a layer different from the gate insulating film.

(10)

The photodetector according to any of (1) to (7) described above, in which
the transistor includes a gate electrode provided over the element formation region and the element isolation region, the transistor including a side wall spacer provided on a sidewall of the gate electrode, and
the second insulating film is provided between the conductive film and the side wall spacer.

(11)

The photodetector according to any of (1) to (8) described above, in which
the transistor includes a gate electrode provided over the element formation region and the element isolation region, and
the transistor is disposed in an orientation in which a channel formation region immediately below the gate electrode is adjacent to the photoelectric converter across the element isolation region.

(12)

The photodetector according to any of (1) to (7) described above, in which
the transistor includes a gate insulating film provided in the element formation region, and
the second insulating film has a larger film thickness than the gate insulating film.

(13)

The photodetector according to any of (1) to (12) described above, the element isolation region further includes a pinning film interposed between the groove and the first insulating film.

(14)

The photodetector according to any of (1) to (11) described above further including
a read circuit that reads a signal charge photoelectrically converted by the photoelectric converter, in which
at least one of a plurality of pixel transistors included in the read circuit is the transistor.

(15)

The photodetector according to any of (1) to (14) described above further including a microlens provided on a side of the second surface of the semiconductor layer.

(16)

The photodetector according to any of (1) to (15) described above, in which the transistor includes a field effect transistor.

(17)

An electronic apparatus including a photodetector, an optical lens that forms an image of image light from a subject on an imaging surface of the photodetector, and a signal processing circuit that performs signal processing on a signal output from the photodetector, in which
the photodetector includes a semiconductor layer that has a first surface and a second surface located opposite to each other and is provided with an element isolation region on a side of the first surface, a photoelectric converter provided in the semiconductor layer, and a transistor provided adjacent to the photoelectric converter on the side of the first surface of the semiconductor layer across the element isolation region, and
the element isolation region includes a conductive film provided in a groove on the side of the first surface of the semiconductor layer with a first insulating film interposed therebetween, and a second insulating film provided on the side of the first surface of the semiconductor layer so as to overlap the conductive film.

The scope of the present technology is not limited to the exemplary embodiments illustrated and described, but includes also all embodiments that produce effects equivalent to the effects that the present technology intends to produce. Furthermore, the scope of the present technology is not limited to the combinations of the features of the invention defined by the claims, and may be defined by any desired combination of specific features among all the disclosed features.

### REFERENCE SIGNS LIST

1A, 1B, 1C, 1D, 1E, 1F, 1G, 1H, 1I, 1J Solid-state imaging device
2 Semiconductor chip
2A Pixel region
2B Peripheral region
3 Pixel
4 Vertical drive circuit
5 Column signal processing circuit
6 Horizontal drive circuit
7 Output circuit
8 Control circuit
10 Pixel drive line
12 Horizontal signal line
13 Logic circuit
14 Bonding pad
15 Pixel block
16A First pixel group
16B Second pixel group
17 Read circuit
21 Semiconductor layer
21a Element formation region
21b Element formation region
22 P-type semiconductor region
23 Photoelectric converter (n-type semiconductor region)
25 Element isolation region (active region)
26 Groove (recess)
27 First insulating film
28 Conductive film
29 Second insulating film
31 Gate insulating film
32a₁, 32a₂, 32a₃, 32f, 32r, 32s, 32t Gate electrode
33 Side wall spacer
34b, 34c, 34d, 34e, 34g, 34h, 34j Main electrode region
35 Pinning film
36 Insulating layer
37a₁, 37a₂, 37a₃, 37b, 37c, 37d, 37e, 35g, 35h, 37j Contact electrode
38 Wiring layer
38a, 38b, 38c, 38d, 38e, 38g, 38h, 38j, 38r, 38s, 38t Wire
41 Pixel isolation region
42 Insulating film
43 Planarization film
44 Light shielding film
45 Color filter
46 Microlens
51 Pixel block
52 Amplification transistor
53 Selection transistor
54 Reset transistor
55 Switching transistor
61 Semiconductor layer
62 P-type semiconductor region
63 Photoelectric converter
64 n-type semiconductor region
65 Element isolation region
66 Groove
67 First insulating film
68 Conductive film
69 Second insulating film
71 Pixel isolation region
80 Transfer transistor
81 Gate insulating film
82 Gate electrode
82a First portion
82b Second portion
85 Contact portion
AMP, AMP1 to 3 Amplification transistor
FD Charge holding region
FDG Switching transistor
RST Reset transistor
Rp1 First reference potential
Rp2 Second reference potential
SEL, SEL1 to 2 Selection transistor
TR Transfer transistor
S1 First surface
S2 Second surface

1. A photodetector comprising:
a semiconductor layer that has a first surface and a second surface located opposite to each other and is provided with an element isolation region on a side of the first surface;
a photoelectric converter provided in the semiconductor layer; and
a transistor provided adjacent to the photoelectric converter on the side of the first surface of the semiconductor layer across the element isolation region, wherein
the element isolation region includes a conductive film provided in a groove on the side of the first surface of the semiconductor layer with a first insulating film interposed therebetween, and a second insulating film provided on the side of the first surface of the semiconductor layer so as to overlap the conductive film.

2. The photodetector according to claim 1, wherein the second insulating film covers the conductive film.

3. The photodetector according to claim 1, wherein the conductive film is electrically connected to a wire to which a potential is applied.

4. The photodetector according to claim 1, wherein
the photoelectric converter includes a first semiconductor region of a first conductivity type, and
a second semiconductor region of a second conductivity type is provided in the semiconductor layer between the element isolation region and the first semiconductor region.

5. The photodetector according to claim 4, wherein the conductive film includes a conductive material having a deeper Fermi level than the second semiconductor region.

6. The photodetector according to claim 4, wherein the conductive film includes a conductive material having a deeper work function than the second semiconductor region.

7. The photodetector according to claim 4, wherein
a reference potential is applied to the second semiconductor region, and
a negative potential lower than the reference potential is applied to the conductive film.

8. The photodetector according to claim 1, wherein
the semiconductor layer includes an element formation region defined by the element isolation region on the side of the first surface,
the transistor includes a gate electrode provided over the element formation region and the element isolation region, and
the second insulating film is interposed between the conductive film and the gate electrode.

9. The photodetector according to claim 1, wherein
the transistor includes a gate insulating film provided in the element formation region, and
the second insulating film is provided in a layer different from the gate insulating film.

10. The photodetector according to claim 1, wherein
the transistor includes a gate electrode provided over the element formation region and the element isolation region, the transistor including a side wall spacer provided on a sidewall of the gate electrode, and
the second insulating film is provided between the conductive film and the side wall spacer.

11. The photodetector according to claim 1, wherein
the transistor includes a gate electrode provided over the element formation region and the element isolation region, and
the transistor is disposed in an orientation in which a channel formation region immediately below the gate electrode is adjacent to the photoelectric converter across the element isolation region.

12. The photodetector according to claim 1, wherein
the transistor includes a gate insulating film provided in the element formation region, and
the second insulating film has a larger film thickness than the gate insulating film.

13. The photodetector according to claim 1, wherein the element isolation region further includes a pinning film interposed between the groove and the first insulating film.

14. The photodetector according to claim 1, further comprising
a read circuit that reads a signal charge photoelectrically converted by the photoelectric converter, wherein
at least one of a plurality of pixel transistors included in the read circuit is the transistor.

15. The photodetector according to claim 1, further comprising a microlens provided on a side of the second surface of the semiconductor layer.

16. The photodetector according to claim 1, wherein the transistor includes a field effect transistor.

17. An electronic apparatus comprising: a photodetector; an optical lens that forms an image of image light from a subject on an imaging surface of the photodetector; and a signal processing circuit that performs signal processing on a signal output from the photodetector, wherein
the photodetector includes a semiconductor layer that has a first surface and a second surface located opposite to each other and is provided with an element isolation region on a side of the first surface, a photoelectric converter provided in the semiconductor layer, and a transistor provided adjacent to the photoelectric converter on the side of the first surface of the semiconductor layer across the element isolation region, and
the element isolation region includes a conductive film provided in a groove on the side of the first surface of the semiconductor layer with a first insulating film interposed therebetween, and a second insulating film provided on the side of the first surface of the semiconductor layer so as to overlap the conductive film.
